(19) United States
(12) Patent Application Publication
(10) Pub. No.: US 2026/0013055 A1
(43) Pub. Date: Jan. 8, 2026

(54) ELECTRONIC DEVICE INCLUDING ACOUSTIC COMPONENT

(71) Applicant: Samsung Electronics Co., Ltd., Suwon-si (KR)

(72) Inventors: Kyungmin PARK, Suwon-si (KR); Minho LEE, Suwon-si (KR); Myungcheol LEE, Suwon-si (KR)

(21) Appl. No.: 19/291,133

(22) Filed: Aug. 5, 2025

Related U.S. Application Data
(63) Continuation of application No. PCT/KR2025/009750, filed on Jul. 7, 2025.

(30) Foreign Application Priority Data
Jul. 8, 2024 (KR) 10-2024-0089599
Aug. 16, 2024 (KR) 10-2024-0109949

(51) Int. Cl. H05K 5/02

(52) U.S. Cl. CPC H05K 5/0214

(57) ABSTRACT

An electronic device may include a housing forming an outer side of the electronic device, a display panel disposed on the housing, a transparent window disposed on the display panel, and forming a front face of the electronic device, a hole formed by at least part of the transparent window, a speaker outputting sound to the outside of the electronic device through at least one acoustic passage formed in the electronic device and through the hole, an air vent passage formed at the housing and configured to equalize air pressure of an inner air space of the electronic device with atmospheric pressure through the hole, and a waterproof member disposed on the air vent passage to allow air to pass therethrough.

### CROSS-REFERENCE TO RELATED APPLICATIONS

This application is a continuation application of International Application No. PCT/KR2025/009750 designating the United States, filed on Jul. 7, 2025, in the Korean Intellectual Property Receiving Office and claiming priority to Korean Patent Application No. 10-2024-0089599, filed on Jul. 8, 2024, and Korean Patent Application No. 10-2024-0109949, filed on Aug. 16, 2024, the disclosures of which are all hereby incorporated by reference herein in their entireties.

### BACKGROUND

### Technical Field

Certain example embodiments may relate to an electronic device including an acoustic component.

### Background Art

An electronic device, such as a smartphone, a tablet Personal Computer (PC), or a wearable device, may include at least one acoustic component. For example, the electronic device may include a speaker and/or a receiver. The acoustic component may output sound to the outside of the electronic device through a hole formed outside the electronic device. The electronic device may maintain equilibrium of pressure inside the electronic device through at least one hole which connects the inside of the electronic device and the outside of the electronic device.

The aforementioned content may be provided as background technologies for aiding understanding of the disclosure. No claim or decision is made as to whether the aforementioned content is applicable as the prior art related to the disclosure.

### SUMMARY

An electronic device according to an example embodiment may include a housing forming an outer side of the electronic device. The electronic device may include a display panel disposed on, directly or indirectly, the housing. The electronic device may include a transparent window disposed on, directly or indirectly, the display panel.

The example transparent window may form a front face of the electronic device. The electronic device may include a hole formed by at least part of the transparent window. The example electronic device may include a speaker outputting sound to the outside of the electronic device through at least one acoustic passage formed in the electronic device and through the hole. An acoustic air space in the electronic device may be connected, directly or indirectly, to the outside through the at least one acoustic passage. The electronic device may include an air vent passage formed at the housing. The air vent passage may be configured to equalize air pressure of an inner air space of the electronic device with atmospheric pressure through the hole. The inner air space, independent with the acoustic air space, of the electronic device may be connected, directly or indirectly, to the outside through the air vent passage. The electronic device may include a waterproof member disposed on, directly or indirectly, the air vent passage to allow air to pass therethrough.

An electronic device according to an example embodiment may include a housing forming a side of the electronic device. The electronic device may include a display panel disposed on, directly or indirectly, the housing. The electronic device may include a front plate disposed on, directly or indirectly, the display panel. The front plate may form a front face of the electronic device. The electronic device may include a slit formed between the side of the electronic device and an edge of the front plate such that the housing and at least part of the edge of the front plate are spaced apart from each other. Sound may be output through the slit. The electronic device may include an acoustic output component outputting the sound to the outside of the electronic device through at least one acoustic passage formed in the electronic device and through the slit. The housing may include an air vent passage open toward the front plate. The air vent passage may connect the slit and an inner air space of the electronic device. The housing may include the air vent passage to form a path for airflow between the outside of the electronic device and the inner air space of the electronic device. The electronic device may include a waterproof member disposed on the path for air flow.

### BRIEF DESCRIPTION OF DRAWINGS

FIG. 1 is a front perspective view of an electronic device according to an example embodiment;

FIG. 2 is a rear perspective view of the electronic device of FIG. 1;

FIG. 3 is an exploded perspective view of the electronic device of FIG. 1;

FIG. 4 is a schematic view illustrating an electronic device according to an example embodiment;

FIG. 5A is an exploded perspective view illustrating a structure of an electronic device according to an example embodiment;

FIG. 5B is a plan view illustrating part of an electronic device including an acoustic passage and an air vent passage according to an example embodiment;

FIG. 6 illustrates a housing including a first passage and a second passage according to an example embodiment;

FIG. 7 is a perspective view of the drawing of FIG. 6, taken along the line A-A′ of FIG. 6;

FIG. 8 is a plan view for explaining an electronic device including a first waterproof member according to an example embodiment;

FIG. 9 is a cross-sectional view of the drawing of FIG. 8, taken along the line B-B′ of FIG. 8;

FIG. 10 is a cross-sectional view of the drawing of FIG. 8, taken along the line C-C′ of FIG. 8;

FIG. 11 is a plan view for explaining an electronic device including a second waterproof member according to an example embodiment;

FIG. 12 is a cross-sectional view of the electronic device of FIG. 11, taken along the line D-D′ of FIG. 11;

FIG. 13 is an exploded perspective view illustrating a structure of an electronic device including a second waterproof member according to an example embodiment;

FIG. 14 is a cross-sectional perspective view for explaining a housing including a third passage according to an example embodiment;

FIG. 15 is a cross-sectional view for explaining a second waterproof member disposed to the electronic device of FIG. 14;

FIG. 16 is a plan view illustrating a rear face of the housing of FIG. 14;

FIG. 17 is a cross-sectional view of the electronic device of FIG. 15, taken along the line E-E′ of FIG. 15;

FIG. 18 is a plan view for explaining a housing including a fourth passage according to an example embodiment;

FIG. 19 is a cross-sectional view of the electronic device of FIG. 18, taken along the line F-F′ of FIG. 18;

FIG. 20 is a perspective view for explaining a housing including a fifth passage and a sixth passage according to an example embodiment; and

FIG. 21 is a plan view of the electronic device of FIG. 20.

### DETAILED DESCRIPTION

Hereinafter, embodiments of the disclosure will be described in detail with reference to the accompanying drawings so that those skilled in the art can easily implement the disclosure. However, the disclosure may be realized in various different forms and is not limited to the embodiments described herein. In addition, in order to clearly describe the disclosure, parts not related to the description are omitted in the drawings, and similar reference numerals are given to similar parts throughout the specification.

Terms used in the disclosure are described as general terms currently in use in consideration of functions mentioned in the disclosure, but may mean various other terms depending on the intention of a technician engaged in the relevant field, precedents, emergence of new technologies, or the like. Therefore, the terms used in the disclosure shall not be interpreted only based on the name of the term, but shall be interpreted based on the meaning of the term and the overall content of the disclosure.

An electronic device according to various embodiments of the disclosure may include, for example, at least one of a smartphone, a tablet Personal Computer (PC), a mobile phone, a video phone, an e-book reader, a desktop PC, a laptop PC, a netbook computer, a workstation, a server, a Personal Digital Assistant (PDA), a Portable Multimedia Player (PMP), an MPEG-1 Audio Layer 3 (MP3) player, a mobile medical device, a camera, and a wearable device. According to various embodiments, the wearable device may include at least one of an accessory-type device (e.g., a watch, a ring, a bracelet, an anklet, a necklace, glasses, contact lenses, or a Head-Mounted Device (HMD)), a fabric- or clothes-integrated device (e.g., electronic clothes), a body attaching-type device (e.g., a skin pad or tattoo), and a body implantable device (e.g., an implantable circuit).

In various embodiments, the electronic device may be one or more combinations of the aforementioned various devices. According to an embodiment, the electronic device may be a flexible electronic device. In addition, the electronic device according to an embodiment of the disclosure is not limited to the aforementioned devices, and may include a new electronic device depending on technical progress.

In addition, the term ‘first’, ‘second’, or the like may be used to describe various components, but the components shall not be limited by these terms. The terms are used to distinguish one component from another.

Throughout the specification, when a part is mentioned to be “connected” to another part, this includes not only a case where it is “directly connected” but also a case where it is “electrically connected” thereto with other element(s) interposed therebetween. Also, when a part is mentioned to “include” a component, this does not mean that it excludes other components, but rather that it may further include other components, unless otherwise specified. Thus, for example, “connected” as used herein covers direct and indirect connections.

Phrases such as “according to an embodiment”, “in an embodiment”, and the like mentioned in various sections of this disclosure do not necessarily all refer to the same embodiment.

The disclosure may provide an electronic device which prevents or reduces chances of a path from being blocked by foreign substances and prevents or reduces chances of an air pressure sensor malfunctioning, by forming the path for airflow inside the electronic device.

The disclosure may provide an electronic device which improves aesthetics of the electronic device by preventing or reducing an increase in holes formed outside the electronic device.

The disclosure may provide an electronic device which improves waterproof performance of the electronic device while maintaining air pressure of an external environment of the electronic device to be equal to air pressure of an inner air space of the electronic device.

An electronic device according to an embodiment of the disclosure may include a passage providing a path allowing air outside the electronic device to move to the inside of the electronic device through a hole (or a slit) through which sound output from an acoustic component is output to the outside of the electronic device, and allowing air inside the electronic device to move to the outside of the electronic device.

Hereinafter, the disclosure will be described in detail with reference to the accompanying drawings.

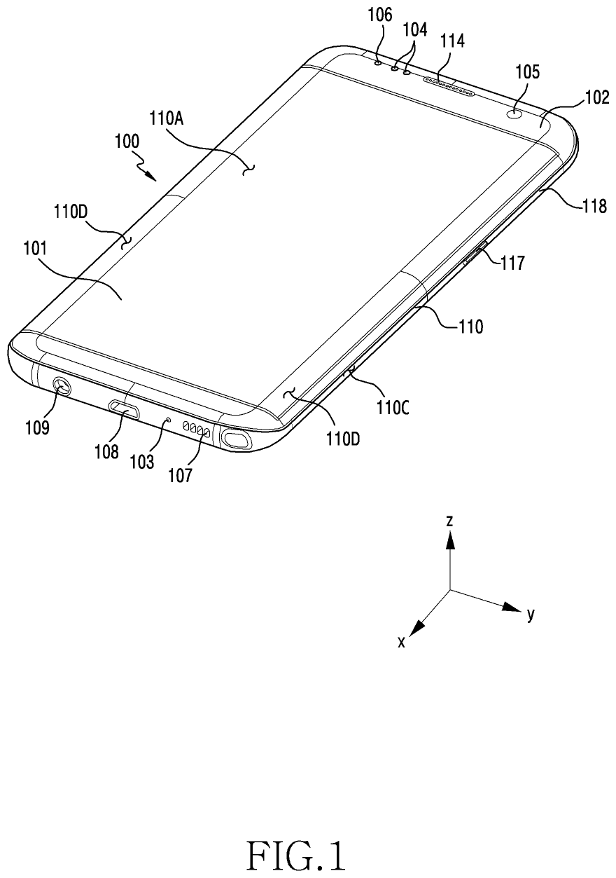

FIG. 1 is a front perspective view of a mobile electronic device according to an embodiment.

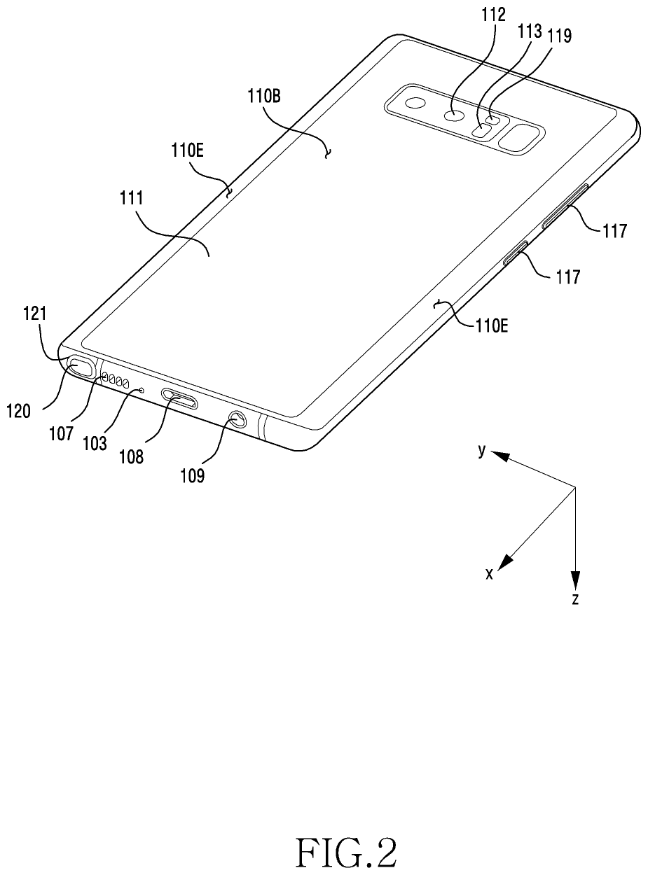

FIG. 2 is a rear perspective view of the electronic device of FIG. 1.

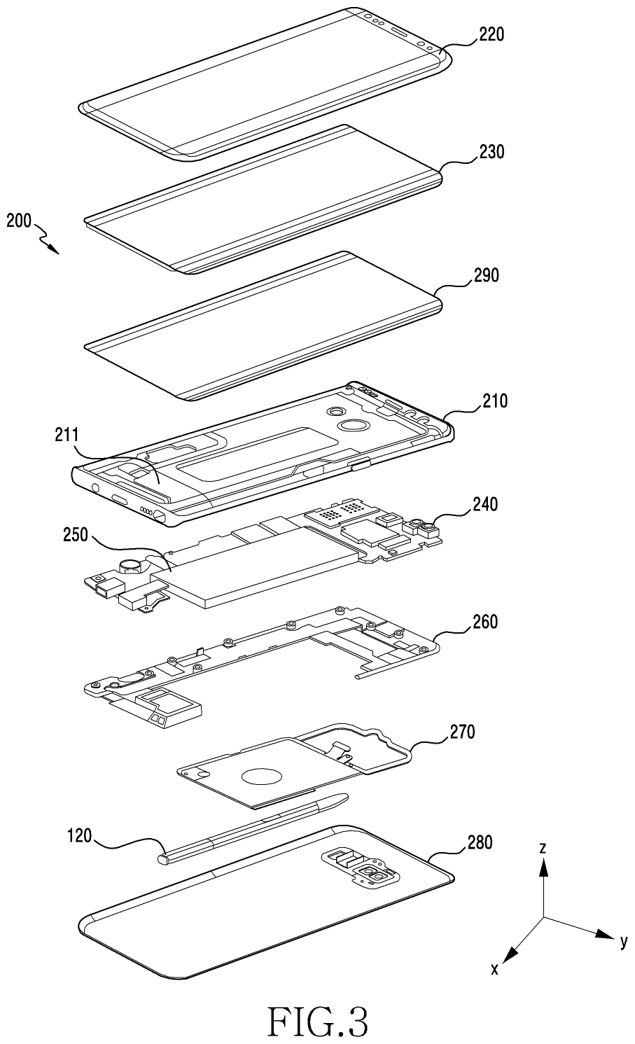

FIG. 3 is an exploded perspective view of the electronic device of FIG. 1.

Referring to FIGS. 1 and 2, an electronic device 100 according to an embodiment may include a housing 110 including a first face (or a front face) 110A, a second face (or a rear face) 110B, and a side face 110C surrounding a space between the first face 110A and the second face 110B. In an embodiment (not shown), the housing may refer to a structure which constitutes part of the first face 110A, second face 110B, and third face 110C of FIG. 1. According to an embodiment, the first face 110A may be constructed of a front plate 102 (e.g., a polymer plate or a glass plate having various coating layers) which is at least partially transparent substantially. The second face 110B may be constructed of a rear plate 111 which is opaque substantially. For example, the rear plate 111 may be constructed of coated or colored glass, ceramic, polymer, metallic materials (e.g., aluminum, stainless steel (STS), or magnesium) or a combination of at least two of the aforementioned materials. The side face 110C may be constructed of a side bezel structure (or a side member) 118 bonded to the front plate 102 and the rear plate 111 and including metal and/or polymer. In some embodiments, the rear plate 111 and the side bezel structure 118 may be constructed integrally and may include the same material (e.g., a metallic material such as aluminum).

In the illustrated embodiment, the front plate 102 may include two first regions 110D seamlessly extended by being bent from the first face 110A toward the rear plate 111 at both ends of a long edge of the front plate 102. In the illustrated embodiment (see FIG. 2), the rear plate 111 may include two second regions 110E seamlessly extended by being bent from the second face 110B toward the front plate 102 at both ends of a long edge. In some embodiments, the front plate 102 (or the rear plate 111) may include only one of the first regions 110D (or the second regions 110E). In an embodiment, some of the first regions 110D or the second regions 110E may not be included. In the above embodiments, when viewed from a side of the electronic device 100, the side bezel structure 118 may have a first thickness (or width) at a side in which the first regions 110D or the second regions 110E is not included, and may have a second thickness thinner than the first thickness at a side in which the first regions 110E or the second regions 110E is included.

According to an embodiment, the electronic device 100 may include at least one of a display 101, audio modules 103, 107, and 114, sensor modules 104, 116, and 119, camera modules 105, 112, and 113, a key input device 117, a light emitting element 106, a pen input device 120, and connector holes 108 and 109. In some embodiments, at least one of the components (e.g., the key input device 117 or the light emitting element 106) may be omitted in the electronic device 100, or other components may be additionally included.

The display 101 may be exposed through, for example, some portions of the front plate 102. In some embodiments, at least part of the display 101 may be exposed through the first face 110A and the front plate 102 constructing the first regions 110E of the side face 110C. In some embodiments, a corner of the display 101 may be constructed to be substantially identical to an adjacent outer perimeter of the front plate 102. In an embodiment (not shown), a spacing between an outer perimeter of the display 101 and the outer perimeter of the front plate 102 may be constructed to be substantially identical in order to enlarge an area to which the display 101 is exposed.

In an embodiment (not shown), a recess or opening may be constructed in part of a screen display region of the display 101, and at least one of the audio module 114, the sensor module 104, the camera module 105, and the light emitting element 106 may be included, which are aligned with the recess or the opening. In an embodiment (not shown), at least one of the audio module 114, the sensor module 104, the camera module 105, the fingerprint sensor 116, and the light emitting element 106 may be included in a rear face of the screen display region of the display 101. In an embodiment (not shown), the display 101 may be disposed adjacent to or bonded to a touch sensing circuit, a pressure sensor capable of measuring touch strength (pressure), and/or a digitizer for detecting a magnetic-type stylus pen. In some embodiments, at least part of the sensor modules 104 and 119 and/or at least part of the key input device 117 may be disposed to the first regions 110D and/or the second regions 110E.

The audio modules 103, 107, and 114 may include the microphone hole 103 or the speaker holes 107 and 114. A microphone for acquiring external sound may be disposed inside the microphone hole 103. In some embodiments, a plurality of microphones may be disposed to detect a direction of the sound. The speaker holes 107 and 114 may include the external speaker hole 107 and the call receiver hole 114. In some embodiments, the speaker holes 107 and 114 and the microphone hole 103 may be implemented as one hole, or a speaker (e.g., a Piezo speaker) may be included without the speaker holes 107 and 114.

The sensor modules 104, 116, and 119 may generate an electrical signal or data value corresponding to an internal operational state of the electronic device 100 or an external environmental state. The sensor modules 104, 116, and 119 may include, for example, the first sensor module 104 (e.g., a proximity sensor) and/or second sensor module (not shown) (e.g., a fingerprint sensor) disposed to the first face 110A of the housing 110, and/or the third sensor module 119 (e.g., a Heart Rate Monitoring (HRM) sensor) disposed to the second face 110B of the housing 110 and/or the fourth sensor module 116 (e.g., a fingerprint sensor). The fingerprint sensor may be disposed to not only the first face 110A but also the second face 110B of the housing 110. The electronic device 100 may further include at least one of senor modules (not shown), for example, a gesture sensor, a gyro sensor, an air pressure sensor, a magnetic sensor, an acceleration sensor, a grip sensor, a color sensor, an Infrared (IR) sensor, a biometric sensor, a temperature sensor, a humidity sensor, and an illuminance sensor 104.

The camera modules 105, 112, and 113 may include the first camera module 105 disposed to the first face 110A of the electronic device 100, the second camera module 112 disposed to the second face 110B, and/or the flash 113. The camera module 105 and 112 may include one or more lenses, an image sensor, and/or an image signal processor. The flash 113 may include, for example, a Light Emitting Diode (LED) or a xenon lamp. In some embodiments, two or more lenses (infrared cameras, wide angle and telephoto lenses) and image sensors may be disposed to one face of the electronic device 100.

The key input device 117 may be disposed to the side face 110C of the housing 110. In an embodiment, the electronic device 100 may not include some or all of the aforementioned key input device 117. The key input device 117, which is not included, may be implemented on the display 101 in a different form such as a soft key or the like. In some embodiments, the key input device may include the sensor module 116 disposed to the second face 110B of the housing 110.

The light emitting element 106 may be disposed to, for example, the first face 110A of the housing 110. The light emitting element 106 may provide, for example, status information of the electronic device 100 in an optical form. In an embodiment, the light emitting element 106 may provide, for example, a light source interworking with an operation of the camera module 105. The light emitting element 106 may include, for example, a Light Emitting Diode (LED), an IR LED, and a xenon lamp.

The connector holes 108 and 109 may include the first connector hole 108 capable of accommodating a connector (e.g., a USB connector) for transmitting/receiving power and/or data with respect to an external electronic device and/or the second connector hole (e.g., an earphone jack) 109 capable of accommodating a connector for transmitting/receiving an audio signal with respect to the external electronic device.

The pen input device 120 (e.g., a stylus pen) may be inserted or detached by being guided to an inner portion of the housing 110 through a hole 121 constructed on the side face of the housing 110, and may include a button for facilitating the detachment. The pen input device 120 may have a separate resonance circuit embedded therein to interwork with an electromagnetic induction panel 290 (e.g., a digitizer) included in the electronic device 100. A type of the pen input device 120 may include an Electro-Magnetic Resonance (EMR) type, an Active Electrical Stylus (AES) type, and an Electric Coupled Resonance (ECR) type.

Referring to FIG. 3, an electronic device 200 may include a side bezel structure 210, a first support member 211 (e.g., a bracket), a front plate 220, a display 230, an electromagnetic induction panel 290, a Printed Circuit Board (PCB) 240, a battery 250, a second support member 260 (e.g., a rear case), an antenna 270, a pen input device 120, and a rear plate 280. In some embodiments, at least one (e.g., the first support member 211 or the second support member 260) of these components may be omitted in the electronic device 200, or other components may be additionally included. At least one of the components of the electronic device 200 may be the same as or similar to at least one of the components of the electronic device 100 of FIG. 1 or FIG. 2, and redundant descriptions will be omitted hereinafter.

The electromagnetic induction panel 290 (e.g., a digitizer) may be a panel for detecting an input of the pen input device 120. For example, the electromagnetic induction panel 290 may include a Printed Circuit Board (PCB) (e.g., a Flexible Printed Circuit Board (FPCB)) and a shielding sheet. The shielding sheet may prevent or reduce mutual interference between components, caused by an electromagnetic field generated from the components (e.g., the display module, the PCB, the electromagnetic induction panel, etc.) included in the electronic device 200. The shielding sheet may block the electromagnetic field generated from the components, so that an input from the pen input device 120 is correctly transferred to a coil included in the electromagnetic induction panel. The electromagnetic induction panel according to various embodiments may include an opening constructed in at least some regions corresponding to a biometric sensor mounted to, directly or indirectly, the electronic device 200.

The first support member 211 may be connected with the side bezel structure 210 by being disposed inside the electronic device 200, or may be constructed integrally with respect to the side bezel structure 210. The first support member 211 may be constructed of, for example, a metal material and/or non-metal material (e.g., polymer). The display 230 may be coupled, directly or indirectly, to one face of the first support member 211, and the PCB 240 may be coupled to the other face thereof. A processor, a memory, and/or an interface may be mounted on, directly or indirectly, the PCB 240. The processor may include, for example, one or more of a central processing unit, an application processor, a graphic processing unit, an image signal processor, a sensor hub processor, and a communication processor. Each “processor” herein includes processing circuitry, and/or may include multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The memory may include, for example, a volatile memory or a non-volatile memory.

The interface may include, for example, a High Definition Multimedia Interface (HDMI), a Universal Serial Bus (USB) interface, a Secure Digital (SD) card interface, and/or an audio interface. For example, the interface may electrically or physically connect the electronic device 200 and the external electronic device, and may include a USB connector, an SD card/MMC connector, or an audio connector.

As a device for supplying power to at least one component of the electronic device 200, the battery 250 may include, for example, a non-rechargeable primary cell, a rechargeable secondary cell, or a fuel cell. At least part of the battery 250 may be disposed on the substantially same plane as, for example, the PCB 240. The battery 250 may be disposed integrally inside the electronic device 200, or may be detachably disposed with respect to the electronic device 200.

The antenna 270 may be disposed between the rear plate 280 and the battery 250. The antenna 270 may include, for example, a Near Field Communication (NFC) antenna, a wireless charging antenna, and/or a Magnetic Secure Transmission (MST) antenna. The antenna 270 may perform short-range communication, for example, with the external electronic device, or may wirelessly transmit/receive power required for charging. In an embodiment, an antenna structure may be constructed by at least part of the side bezel structure 210 and/or the first support member 211 or a combination thereof.

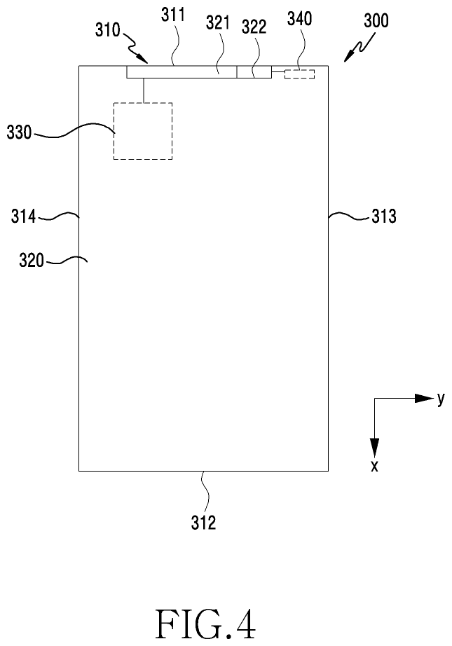

FIG. 4 is a schematic view illustrating an electronic device according to an embodiment.

The electronic device of FIG. 4 and components thereof may be referenced by electronic devices of other drawings and components thereof. The same terms and/or the same reference numerals have been used for the same or substantially the same components as those described above.

Referring to FIG. 4, an electronic device 300 according to an embodiment may include a housing 310, a window 320 (e.g., the front plate 102 of FIG. 1), a hole 321, an acoustic component 330, and an air vent passage 340. However, the electronic device 300 is not limited to this structure. For example, at least one of the aforementioned components may be omitted in the electronic device 300, or at least one different component may be additionally included. For example, the electronic device 300 may further include at least one of a display panel (not shown) disposed below the window 320, a waterproof member (not shown) disposed on the air vent passage 340, or an adhesive member (not shown) which adheres the display panel to the housing 310. In an example, a display (e.g., the display 101 of FIG. 1) may include the window 320 and/or the display panel. However, the disclosure is not limited thereto.

According to an embodiment, the housing 310 may form an exterior of the electronic device 300. For example, the housing 310 may form an outer side of the electronic device 300. For example, a side (e.g., a first side 311) of the housing 310 may form a side of the electronic device 300.

According to an embodiment, the housing 310 may include the first side 311 and a second side 312 opposite the first side 311. However, the disclosure is not limited thereto. For example, the housing 310 may further include a third side 313 facing a direction substantially perpendicular to the first and second sides 311 and 312, and a fourth side 314 opposite the third side 313.

According to an embodiment, the window 320 may be disposed to face a direction substantially perpendicular to a side of the housing 310. For example, the window 320 may be disposed to the housing 310 to face a direction substantially perpendicular to the first side 311.

According to an embodiment, at least part of the window 320 may form the hole 321 (e.g., the call receiver hole 114 of FIG. 1). For example, the window 320 may form the housing 310 and the hole 321. For example, the hole 321 may be formed between the window 320 and the housing 310. For example, the hole 321 may be formed between the housing 310 and an edge of the window 320. For example, the hole 321 may be formed between an edge of the housing 310 and the edge of the window 320. For example, the hole 321 may be formed between a first edge 322 of the window 320 and the first side 311 of the housing 310.

According to an embodiment, the window 320 may form a front face (e.g., the front face 110A of FIG. 1) of the electronic device 300. In an example, the window 320 may include a transparent material. For example, in the disclosure, the window 320 may be referred to as a transparent window. However, the disclosure is not limited thereto. For example, the window 320 may be referred to as a front plate and/or a front cover.

According to an embodiment, the hole 321 may be formed by at least part of the window 320. For example, the hole 321 may be formed as a gap in which the housing 310 and an edge (e.g., the first edge 322) of the window 320 are spaced apart from each other by a specific interval. However, the hole 321 is not limited to this shape. For example, the hole 321 may have a shape of a groove formed on the window 320. For example, the hole 321 may have a shape of a groove formed on a side (e.g., the first side 311) of the housing 310. In an example, the hole 321 may have a shape of a slit. In the disclosure, the hole 321 may be referred to as at least one of the slit, the groove, and an opening.

According to an embodiment, a longitudinal direction of the hole 321 may be a direction substantially perpendicular to a longitudinal direction of the electronic device 300. For example, the longitudinal direction of the electronic device 300 may be a direction (e.g., an x-axis direction) from the first side 311 of the housing 310 toward the second side 312. The longitudinal direction of the hole 321 may be a direction (e.g., a y-axis direction) substantially perpendicular to the direction from the first side 311 of the housing 310 toward the second side 312. For example, the longitudinal direction of the hole 321 may be a direction from the third side 313 of the housing 310 toward the fourth side 314. However, the disclosure is not limited thereto.

According to an embodiment, the acoustic component 330 may be disposed inside the electronic device 300. For example, the acoustic component 330 may be positioned between the window 320 and a first support member 211 of the housing 310. For example, the acoustic component 330 may be disposed to the first support member 211. However, the disclosure is not limited thereto.

According to an embodiment, the acoustic component 330 may include a speaker and/or a receiver.

According to an embodiment, the acoustic component 330 may be connected, directly or indirectly, to the hole 321. For example, an output passage of sound output from the acoustic component 330 may be connected to the hole 321. For example, the sound output from the acoustic component 330 may be output to the outside of the electronic device 300 through the hole 321 through an acoustic air space.

According to an embodiment, the acoustic component 330 may be disposed at a position adjacent to an edge of the electronic device 300. For example, the acoustic component 330 may be disposed at a position adjacent to an upper end of the electronic device 300. For example, the acoustic component 330 may be disposed at a position adjacent to the first side 311. For example, the acoustic component 330 may be positioned closer to the first side 311 than the second side 312 of the housing 310. For example, the acoustic component 330 may be disposed at a position adjacent to the fourth side 314. For example, the acoustic component 330 may be positioned closer to the fourth side 314 than the third side 313 of the housing 310. However, the disclosure is not limited thereto.

According to an embodiment, the electronic device 300 may include the air vent passage 340. For example, the housing 310 may include at least part of the air vent passage 340. For example, at least part of the air vent passage 340 may be formed at the housing 310. The air vent passage 340 may connect the hole 321 and an inner air space of the electronic device 300. For example, the air vent passage 340 may be formed by at least partially penetrating the housing 310.

According to an embodiment, at least part of the air vent passage 340 may be formed to face the first face of the housing 310 to which the window 320 (and/or the display panel) is disposed from the hole 321 of the housing 310. Referring to FIG. 3 together, the air vent passage 340 may penetrate at least part of the side bezel structure 210 and/or first support member 211. However, the disclosure is not limited thereto. For example, the air vent passage 340 may also penetrate the housing 310 to face the second face of the housing 310, opposite the first face, from the first face of the housing 310 to which the window 320 is disposed.

According to an embodiment, the air vent passage 340 may extend from the hole 321. In an example, referring to FIG. 4, the air vent passage 340 may be formed at a position adjacent to the first side 311 of the housing 310. For example, the air vent passage 340 may be positioned closer to the first side 311 than the second side 312 of the housing 310.

According to an embodiment, the housing 310 may include the air vent passage 340 to form a path for airflow between the outside of the electronic device 300 and the inner air space of the electronic device 300. For example, the housing 310 may include the air vent passage 340 to form a path which equalizes air pressure between an external environment of the electronic device 300 and the inner air space of the electronic device 400.

For example, air may move to the outside of the electronic device 300 through the hole 321 from the inside of the electronic device through the air vent passage 340. For example, the air may flow to the outside of the electronic device 300 through the hole 321 from the inside of the electronic device 300 by means of the air vent passage 340.

For example, the air flowing thereinto through the hole 321 from the outside of the electronic device 300 by means of the air vent passage 340 may move to the inside of the electronic device 300. For example, the air may flow to the inside of the electronic device 300 from the outside of the electronic device through the hole 321 by means of the air vent passage 340.

Therefore, the air pressure between the inside of the electronic device 300 and the external environment of the electronic device 300 may be equalized. For example, since the air passes between the inner air space of the electronic device 300 and the outside of the electronic device 300, inner air pressure of the electronic device 300 and air pressure (e.g., atmospheric pressure) of the external environment of the electronic device 300 may be substantially equalized.

According to an embodiment, the air vent passage 340 may be disposed adjacent to an edge of the hole 321. For example, the air vent passage 340 may be disposed adjacent to one end of the hole 321. For example, the air vent passage 340 may be disposed adjacent to one end close to the third side 313 of the housing 310. For example, the air vent passage 340 may be disposed adjacent to one end facing the third side 313 of the housing 310. However, the disclosure is not limited thereto. For example, the air vent passage 340 may be disposed adjacent to the other end of the hole 321. For example, the air vent passage 340 may be disposed adjacent to the other end close to the fourth side 314 of the housing 310. For example, the air vent passage 340 may be disposed adjacent to the other end facing the fourth side 314.

According to an embodiment, since the air vent passage 340 is connected, directly or indirectly, to the hole 321 and thus is disposed adjacent to the edge of the hole 321, the acoustic component 330 is prevented or reduced from performance deterioration caused by the air passing through the air vent passage 340.

According to an embodiment, the air vent passage 340 may be formed between the holes 321 and the third side 313 of the housing 310. However, the disclosure is not limited thereto. For example, a position at which the air vent passage 340 is formed may vary. For example, the air vent passage 340 may be formed between the hole 321 and the fourth side 314 of the housing 310. For example, the air vent passage 340 may be formed at a position closer to the fourth side 314 than the third side 313 of the housing 310.

In an example, the air vent passage 340 may be formed at various positions adjacent to the hole 321. The air vent passage 340 may be formed at various positions connected to the hole 321. For example, the air vent passage 340 may be formed at a position connected to an output path of sound output from the acoustic component 330. For example, the air vent passage 340 may also be formed between the hole 321 and the acoustic component 330, when looking down the electronic device 300. Although it is described hereinafter, including FIG. 4, that the air vent passage 340 is formed at a position adjacent to the third side 313, this is for convenience of explanation, and the disclosure is not limited thereto.

According to an embodiment, the air vent passage 340 may be open in a direction toward the window 320 (and/or the display panel). For example, the air vent passage 340 may be open in a direction from the housing 310 toward the window 320. For example, an open portion of the air vent passage 340 may at least partially face a rear face of the window 320 (or the display panel). For example, the air vent passage 340 may be disposed below the window 320.

According to an embodiment, the air vent passage 340 may not be visible to the outside of the electronic device 300 due to the window 320. For example, the window 320 may cover the air vent passage 340. Therefore, an outer hole for ventilation of the electronic device 300 may not be formed on an outer side of the electronic device 300, and aesthetics of the electronic device 300 may be improved.

According to an embodiment, the air vent passage 340 may have various shapes. For example, at least part of the air vent passage 340 may have a cylindrical tube shape. However, the disclosure is not limited thereto. For example, the air vent passage 340 may be an N-gonal shape such as a triangle or a square. In an example, at least part of the air vent passage 340 may include a recess which forms an air space open in one direction.

According to an embodiment, the air vent passage 340 may be formed at the housing 310 through CNC processing. However, the disclosure is not limited thereto.

According to an embodiment, the air vent passage 340 may include one or more passages (e.g., a second passage) and/or one or more air spaces (e.g., a first air space). For example, the air vent passage 340 may be an air space in which one or more passages are coupled. For example, the air vent passage 340 may be an air space in which one or more air spaces are coupled, directly or indirectly. For example, the air vent passage 340 may be an air space in which one or more passages and one or more air spaces are coupled.

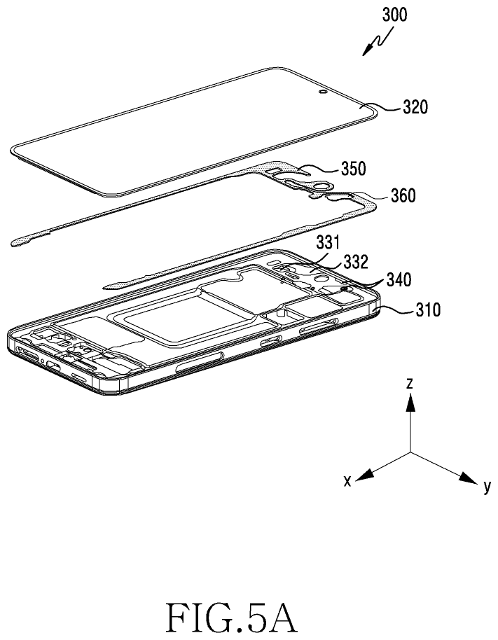

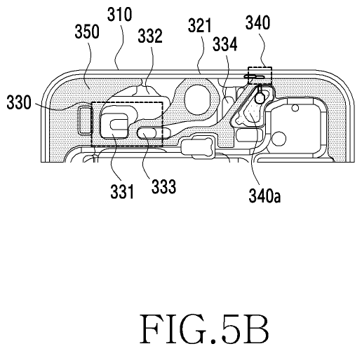

FIG. 5A is an exploded perspective view illustrating a structure of an electronic device according to an embodiment.

The electronic device of FIG. 5A and components thereof may be referenced by electronic devices of other drawings and components thereof. The same terms and/or the same reference numerals have been used for the same or substantially the same components as those described above.

Referring to FIG. 5A, an electronic device 300 according to an embodiment may include a display (e.g., the display 101 of FIG. 1), a housing 310 (e.g., the first support member 211 of FIG. 3), an adhesive member 350, and/or a waterproof member (e.g., a first waterproof member 360). However, the electronic device 300 is not limited to this structure. For example, at least one of the aforementioned components may be omitted in the electronic device 300, or at least one different component may be additionally included. In an example, the at least one different component may be included in the aforementioned components. For example, the adhesive member 350 and the waterproof member may be formed integrally.

According to an embodiment, the display may include a window 320 and/or a display panel. In an example, the display panel may be disposed below the window 320. For example, the display panel may be disposed between the window 320 and the housing 310.

According to an embodiment, the housing 310 may include at least one acoustic hole. For example, the housing 310 may include a first acoustic hole 331. For example, the first acoustic hole 331 may be formed in a shape of a hole and/or opening penetrating the housing 310. For example, in the disclosure, the acoustic hole may be referred to as an acoustic output hole.

According to an embodiment, the electronic device 300 may include at least one acoustic passage formed in the electronic device 300. For example, the electronic device 300 may include at least one acoustic passage formed between the at least one acoustic hole and a hole (e.g., the hole 321 of FIG. 4). For example, a first acoustic passage 332 may be formed between the first acoustic hole 331 and the hole. For example, the first acoustic passage 332 may include a passage formed by joining a display panel 320a and the housing 310.

According to an embodiment, the at least one acoustic passage may be formed between the at least one acoustic hole and the hole. For example, the at least one acoustic passage may connect the at least one acoustic hole and the hole.

According to an embodiment, the at least one acoustic passage may include an air space formed in such a manner that a display (e.g., the display 101 of FIG. 1) and the housing 310 (e.g., the first support member 211 of FIG. 3) are spaced apart from each other. For example, the at least one acoustic passage may be formed in such a manner that a display panel (not shown) and the housing 310 are spaced apart by means of the adhesive member 350.

According to an embodiment, an acoustic component (e.g., the acoustic component 330 of FIG. 4) may be disposed to at least one acoustic air space. For example, the at least one acoustic air space may include an inner air space of at least one acoustic hole (e.g., the first acoustic hole 331) and/or an air space formed between a rear cover and the acoustic component for sound amplification. According to an embodiment, the at least one acoustic air space in the electronic device may be connected to the outside of the electronic device through the at least one acoustic passage (e.g., the first acoustic passage 332).

According to an embodiment, sound output from an acoustic component (e.g., the acoustic component 330 of FIG. 4) (e.g., sound output from the acoustic air space) may pass through the first acoustic hole 331. The sound passing through the first acoustic hole 331 may pass through the first acoustic passage 332. The sound passing through the first acoustic passage 332 may be output to the outside of the electronic device through the hole.

According to an embodiment, the adhesive member 350 may be disposed between the window 320 and the housing 310. For example, the adhesive member 350 may be disposed between the housing 310 and a display panel (not shown) positioned below the window 320. The adhesive member 350 may be at least partially in contact with the display panel and the housing 310. For example, the adhesive member 350 may adhere the display panel to the housing 310.

According to an embodiment, the adhesive member 350 may include at least one of an adhesive tape, a bond, and silicon. However, the disclosure is not limited thereto. For example, the adhesive member 350 may include a waterproof member. For example, the adhesive member 350 may include a waterproof material.

According to an embodiment, the waterproof member (e.g., the first waterproof member 360) may be disposed between a display and the housing 310. For example, the waterproof member may be disposed between a display panel and the housing 310. In an example, the waterproof member may be disposed on a path for airflow between an inner air space of the electronic device and the outside of the electronic device. For example, the waterproof member may be disposed on the path allowing air to pass therethrough. For example, the waterproof member may be disposed on an air vent passage 340. For example, the waterproof member may cover at least part of the air vent passage 340.

According to an embodiment, the waterproof member may be disposed between the window 320 and the air vent passage 340. For example, the waterproof member may be disposed between the air vent passage 340 and a rear cover (not shown).

According to an embodiment, the waterproof member may include a material which allows gas to pass and blocks inflow of liquid (e.g., water) and solids. For example, the waterproof member may include a mesh material. However, the waterproof member is not limited to this type.

According to an embodiment, the adhesive member 350 and the waterproof member (e.g., the first waterproof member 360) may separate the inner air space of the electronic device. For example, the adhesive member 350 and the waterproof member may separate the inner air space of the electronic device into a waterproof region and a non-waterproof region. For example, the adhesive member 350 and the waterproof member may separate an air space formed by disposing a display (e.g., a display panel) on the housing 310. For example, the adhesive member 350 and the waterproof member may separate an air space formed by joining the housing 310 and the display panel. For example, the adhesive member 350 and the waterproof member may separate the air space formed by joining the housing 310 and the display panel into the waterproof region and the non-waterproof region. For example, the adhesive member 350 and the waterproof member may form a region including the acoustic air space as the non-waterproof region.

Hereinafter, a shape of the air vent passage 340 will be described in detail.

FIG. 5B is a plan view illustrating part of an electronic device including an acoustic passage and an air vent passage according to an embodiment.

Components of FIG. 5B may be referenced by components of other drawings. The same terms and/or the same reference numerals have been used for the same or substantially the same components as those described above.

According to an embodiment, a housing 310 (e.g., the first support member 211 of FIG. 3) may form an acoustic hole through which sound output from an acoustic component 330 (e.g., a speaker) moves. For example, at least one acoustic hole (e.g., a first acoustic hole 331) may be formed at the housing 310 (e.g., the first support member 211 of FIG. 3).

According to an embodiment, the at least one acoustic hole may include the first acoustic hole 331 and/or a second acoustic hole 333. According to an embodiment, the at least one acoustic hole may be formed at a position adjacent to the acoustic component 330. The at least one acoustic hole may be formed by penetrating the housing 310 (e.g., the first support member 211 of FIG. 3).

According to an embodiment, at least one acoustic passage may be formed between a display (e.g., the display panel of FIG. 5B) and the housing 310 (e.g., the first support member 211 of FIG. 3). For example, the at least one acoustic passage may include an air space formed in such a manner that the display panel and the housing 310 are spaced apart by an adhesive member 350. According to an embodiment, the at least one acoustic passage may include a first acoustic passage 332 and/or a second acoustic passage 334.

According to an embodiment, the first acoustic passage 332 may connect the first acoustic hole 331 and a hole 321. The second acoustic passage 334 may connect the second acoustic hole 333 and the hole 321.

According to an embodiment, the first acoustic passage 332 may connect at least one acoustic air space (e.g., the at least one acoustic air space of FIG. 5A) and the outside of the electronic device. The second acoustic passage 334 may connect the at least one acoustic air space and the outside of the electronic device.

According to an embodiment, the at least one acoustic air space may be connected to the outside of the electronic device through the at least one acoustic passage. For example, the acoustic air space may be connected to the outside of the electronic device through the first acoustic passage 332. For example, the acoustic air space may be connected to the outside of the electronic device through the first acoustic passage 332 and the hole 321. For example, the acoustic air space may be connected to the outside of the electronic device through the second acoustic passage 334. For example, the acoustic air space may be connected to the outside of the electronic device through the second acoustic passage 334 and the hole 321.

According to an embodiment, the first acoustic passage 332 and the second acoustic passage 334 may be separated by at least part of the adhesive member 350. For example, a first portion of the adhesive member 350 may be disposed between the first acoustic passage 332 and the second acoustic passage 334.

According to an embodiment, the first acoustic passage 332 and/or the second acoustic passage 334 may include an air space formed by being surrounded by the housing 310 (e.g., the first support member 211 of FIG. 3), the display panel, and the adhesive member 350.

According to an embodiment, the acoustic component 330 (e.g., a speaker) may output sound to the outside of the electronic device through at least one acoustic hole (e.g., a first acoustic hole 311), at least one acoustic passage (e.g., the first acoustic passage 332), and/or the hole 321. For example, the at least one acoustic passage may connect the at least one acoustic air space and the hole 321. For example, the acoustic component 330 may output the sound to the outside of the electronic device through the at least one acoustic air space, the at least one acoustic passage, and the hole 321.

According to an embodiment, the electronic device (e.g., the housing 310) may include another passage different from the at least one acoustic passage. For example, the electronic device (e.g., the electronic device 300 of FIG. 4) may include an air vent passage 340.

According to an embodiment, the electronic device (e.g., the electronic device 300 of FIG. 4) may include an inner air space 340a independent with at least one acoustic air space. For example, the at least one acoustic air space may be an air space different from the inner air space 340a. The inner air space 340a independent with the at least one acoustic air space may be connected, directly or indirectly, to the outside of the electronic device through the air vent passage 340. For example, the inner air space 340a may be connected to the outside of the electronic device through the air vent passage 340 and the hole 321. According to an embodiment, the air vent passage 340 may be configured to equalize air pressure of the inner air space 340a of the electronic device with atmospheric pressure through the hole 321.

In an example, air pressure of the at least one acoustic air space may differ from air pressure of the inner air space 340a of the electronic device. For example, the air pressure of the at least one acoustic air space may differ from the atmospheric pressure. However, the disclosure is not limited thereto. For example, the air pressure of the at least one acoustic air space may be equal to the air pressure of the inner air space 340a of the electronic device. For example, the air pressure of the at least one acoustic air space may be equal to the atmospheric pressure.

According to an embodiment, at least one acoustic passage may be separated from the inner air space 340a by means of at least part of the adhesive member 350. For example, a second portion different from a first portion of the adhesive member 350 may be disposed between the at least one acoustic passage and the inner air space 340a. For example, referring to FIG. 5B, the second portion of the adhesive member 350 may be disposed between the second acoustic passage 334 and the inner air space 340a.

According to an embodiment, the inner air space 340a may include an air space formed by being surrounded by the housing 310 (e.g., the first support member 211 of FIG. 3), a display panel, and the adhesive member 350. However, the disclosure is not limited thereto. For example, the inner air space 340a may include an air space surrounded by the housing 310 (e.g., the first support member 211 of FIG. 3) and a rear cover (e.g., the rear plate 111 of FIG. 2).

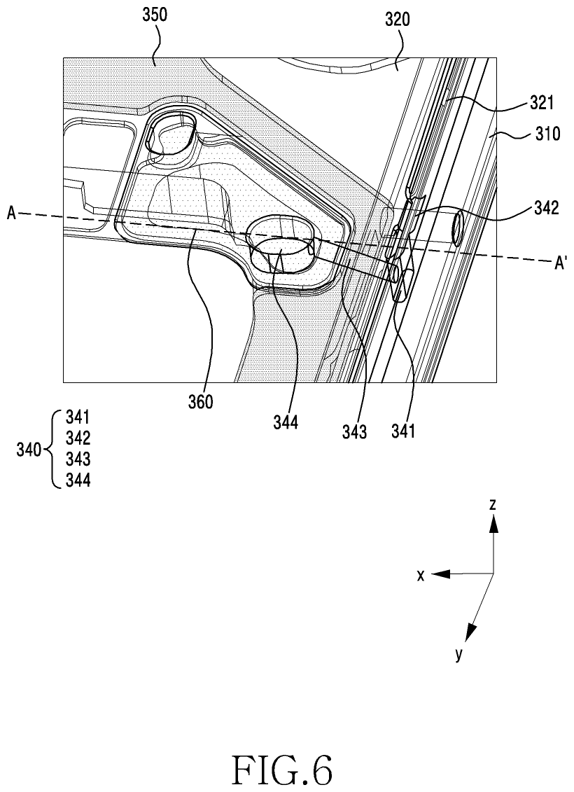

FIG. 6 illustrates a housing including a first passage and a second passage according to an embodiment.

Components of FIG. 6 may be referenced by components of other drawings. The same terms and/or the same reference numerals have been used for the same or substantially the same components as those described above.

Referring to FIG. 6, the electronic device may include a first air space 341 formed at a position adjacent to a hole 321. For example, a housing 310 may include the first air space 341. For example, an air vent page 340 may include the first air space 341. The first air space 341 may be formed at the housing 310.

According to an embodiment, the air vent passage 340 may include the first air space 341, a first passage 342, a second passage 343, and/or a second air space 344.

According to an embodiment, the first air space 341 may be open in a direction (e.g., a +z direction) toward a window 320. The first air space 341 may be formed in the window 320 to have a first depth in a direction (e.g., a −z direction) toward the housing 310. For example, the first air space 341 may be formed as a recess which is open in a direction toward the window 320.

According to an embodiment, the electronic device may include the first passage 342 positioned between the hole 321 and the first air space 341. For example, the housing 310 may include the first passage 342. For example, the air vent passage 340 may include the first passage 342. The first passage 342 may connect the hole 321 and the first air space 341.

According to an embodiment, the first passage 342 may be formed at the housing 310 (e.g., the first support member 211 of FIG. 3). For example, the first passage 342 may include a passage which penetrates the housing 310. However, the disclosure is not limited thereto. For example, the first passage 342 may be formed by the housing 310 and the window 320. For example, the first passage 342 may be formed by coupling the housing 310 and the window 320. For example, the first passage 342 may be formed as a gap spaced apart between the housing 310 and the window 320. For example, the first passage 342 may be formed by the window 320, a display panel (not shown) disposed below the window 320, an adhesive member 350, and/or the housing 310.

According to an embodiment, the electronic device may include the second air space 344 formed at a position adjacent to the first air space 341. For example, the housing 310 may include the second air space 344. For example, the air vent passage 340 may include the second air space 344. The second air space 344 may be formed at the housing 310.

According to an embodiment, the second air space 344 may be open in a direction (e.g., a +z direction) toward a display panel (e.g., the window 320). The second air space 344 may be formed to have a second depth in a direction (e.g., a −z direction) toward the housing 310. For example, the second air space 344 may be formed as a recess which is open in the direction toward the display panel (and/or the window 320).

According to an embodiment, a volume of the first air space 341 may differ from a volume of the second air space 344. For example, the volume of the second air space 344 may be greater than the volume of the first air space 341. However, the disclosure is not limited thereto.

According to an embodiment, the electronic device may include the second passage 343 which connects the first air space 341 and the second air space 344. For example, the housing 310 may include the second passage 343. For example, the air vent passage 340 may include the second passage 343.

According to an embodiment the second passage 343 may be positioned between the first air space 341 and the second air space 344. For example, the second passage 343 may be formed between the first air space 341 and the second air space 344. For example, the second passage 343 may be formed between the first air space 341 and the second air space 344 by penetrating the housing 310.

According to an embodiment, a waterproof member may include a first waterproof member 360 disposed between a display panel and the air vent passage 340. For example, the first waterproof member 360 may be disposed between the display panel and the second air space 344. For example, the first waterproof member 360 may cover the second air space 344.

According to an embodiment, air flowing into the second space 344 may flow into an inner air space of the electronic device (e.g., an air space formed by the display panel, the adhesive member 350, and the first waterproof member 360) by passing through the first waterproof member 360. The air in the inner air space of the electronic device may move to the second air space 344 by passing through the first waterproof member 360.

According to an embodiment, the first waterproof member 360 may block water or foreign substances (e.g., dust) flowing into the inner air space of the electronic device from the second air space 344.

According to an embodiment, at least some of the components of the air vent passage 340 may be omitted in the electronic device, or at least one component may be additionally included. For example, the electronic device may not include the second air space 344. However, the disclosure is not limited thereto.

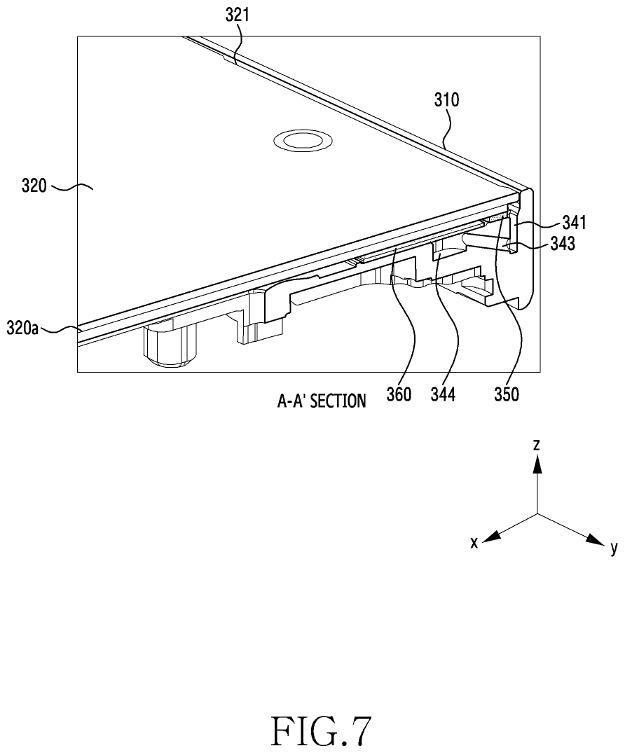

FIG. 7 is a perspective view of the drawing of FIG. 6, taken along the line A-A′ of FIG. 6.

Components of FIG. 7 may be referenced by components of other drawings. The same terms and/or the same reference numerals have been used for the same or substantially the same components as those described above.

According to an embodiment, a display panel 320a may be supported, directly or indirectly, by a housing 310 (e.g., the first support member 211 of FIG. 3). For example, the display panel 320a may be disposed above the housing 310. For example, the display panel 320a may be disposed on, directly or indirectly, the housing 310. For example, “on” as used herein covers both directly and indirectly on.

According to an embodiment, a window 320 may be supported, directly or indirectly, by the housing 310 (e.g., the first support member 211 of FIG. 3). The window 320 may be supported by the display panel 320a. For example, the window 320 may be disposed above the display panel 320a. For example, the window 320 may be disposed on, directly or indirectly, the display panel 320a. For example, the display panel 320a may be disposed between the window 320 and the housing 310.

According to an embodiment, air may flow into the inside of the electronic device through a hole 321. The air flowing thereinto through the hole 321 may sequentially pass through a first passage (e.g., the first passage 342 of FIG. 6), a first air space 341, a second passage 343, and a second air space 344. The air may flow into the inside of the electronic device by passing through a first waterproof member 360.

According to an embodiment, the air inside the electronic device may pass through the first waterproof member 360. The air passing through the first waterproof member 360 may sequentially pass through the second air space 344, the second passage 343, the first air space 341, and a first passage 342, and may move to the outside of the electronic device through the hole 321.

According to an embodiment, liquid may flow into the inside of the electronic device through the hole 321. The liquid flowing thereinto through the hole 321 may sequentially pass through a first passage (e.g., the first passage 342 of FIG. 6), the first air space 341, the second passage 343, and the second air space 344. An adhesive member 350 and the first waterproof member 360 may block the liquid from flowing into an inner air space of the electronic device.

According to an embodiment, the first air space 341 may be formed in the window 320 to have a first depth in a direction (e.g., a −z direction) toward the housing 310. The second air space 344 may be formed in the panel 320a to have a second depth in the direction (e.g., the −z direction) toward the housing 310.

According to an embodiment, the first depth of the first air space 341 may differ from the second depth of the second air space 344. For example, the first depth may be greater than or equal to the second depth. However, the disclosure is not limited thereto.

According to an embodiment, the first air space 341 may have a first width in a direction (e.g., an x-axis direction) in which a side of the housing 310 faces. The second air space 344 may have a second width in a direction in which the side of the housing 310 faces.

According to an embodiment, the first width of the first air space 341 may be less than or equal to the second width of the second air space 344. However, the disclosure is not limited thereto.

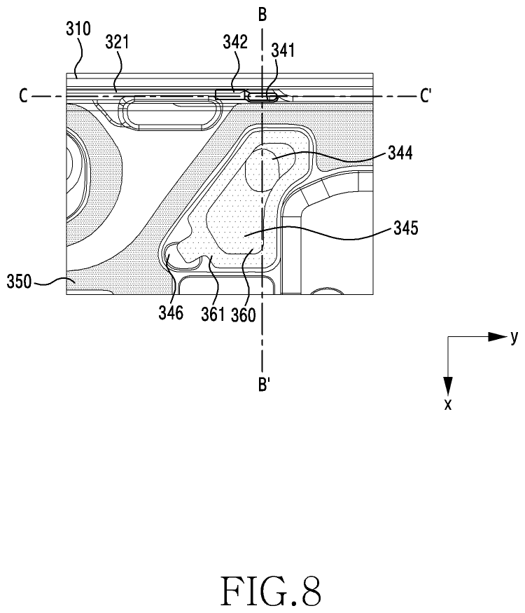

FIG. 8 is a plan view for explaining an electronic device including a first waterproof member according to an embodiment.

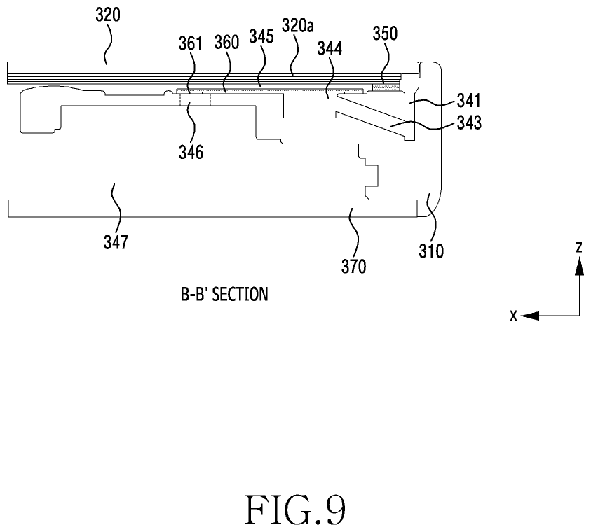

FIG. 9 is a cross-sectional view of the drawing of FIG. 8, taken along the line B-B′ of FIG. 8.

Components of FIG. 8 and FIG. 9 may be referenced by components of other drawings. The same terms and/or the same reference numerals have been used for the same or substantially the same components as those described above.

Referring to FIG. 8, according to an embodiment, an area of an open portion of a first air space 341 may differ from an area of an open portion of a second air space 344. For example, the area of the open portion of the second air space 344 may be greater than or equal to the area of the open portion of the first air space 341. However, the disclosure is not limited thereto.

According to an embodiment, a first waterproof member 360 may be disposed at a position corresponding to the second air space 344. For example, the first waterproof member 360 may overlap the second air space 344. According to an embodiment, a size of the first waterproof member 360 may be greater than an open area of the second air space 344.

According to an embodiment, the first waterproof member 360 may include an adhesive portion 361 which fixes the first waterproof member 360 to a housing 310. The adhesive portion 361 may be disposed between the first waterproof member 360 and the housing 310. In an example, the adhesive portion 361 may be disposed to surround the second air space 344.

According to an embodiment, the housing 310 may include an opening 346 penetrating the housing 310. The opening 346 may be formed at a position adjacent to the second air space 344. In an example, an open area of the opening 346 may be substantially equal to an open area of the second air space 344. However, the disclosure is not limited thereto. In an example, the housing 310 may include the plurality of openings 346.

Referring to FIG. 9, according to an embodiment, an electronic device (e.g., the electronic device 300 of FIG. 5A) may include a rear cover 370 (e.g., the rear plage 111 of FIG. 3) disposed on, directly or indirectly, a housing 310 (e.g., the first support member 211 of FIG. 3). The rear cover 370 may be disposed opposite a display (e.g., the display 101 of FIG. 1) with respect to the housing 310. For example, the rear cover 370 may be disposed opposite a window 320 (and/or a display panel 320a) with respect to the housing 310. For example, the housing 310 may be disposed between the display panel 320a and the rear cover 370.

According to an embodiment, an inner air space of the electronic device may include a first inner air space 345 between the housing 310 and a display (e.g., the window 320 and/or the display panel 320a), and a second inner air space 347 between the housing 310 and the rear cover 370. According to an embodiment, the first inner air space 345 may include an air space formed by the housing 310, the display panel 320a, an adhesive member 350, and a first waterproof member 360. For example, the first inner air space 345 may include an air space formed by being surrounded by the housing 310, the display 320a, the adhesive member 350, and the first waterproof member 360.

According to an embodiment, the second inner air space 347 may include an air space formed by the housing 310 and the rear cover 370. For example, the second inner air space 347 may include an air space formed by being surrounded by the housing 310 and the rear cover 370.

According to an embodiment, an opening 346 may be positioned between the first inner air space 345 and the second inner air space 347. For example, the opening 346 may be formed between the first inner air space 345 and the second inner air space 347. The opening 346 may connect the first inner air space 345 and the second inner air space 347. For example, air in the first inner air space 345 may flow into or out of the second inner air space 347 by passing through the opening 346. For example, air in the second inner air space 347 may flow into or out of the first inner air space 345 by passing through the opening 346.

According to an embodiment, air outside the electronic device may flow into the inside of the electronic device through a hole (e.g., the hole 321 of FIG. 8). For example, the air outside of the electronic device may flow into the inside of the electronic device through the hole, and may pass through a first passage (e.g., the first passage 342 of FIG. 8). The air passing through the first passage may flow into a second air space 344 by sequentially passing through a first air space 341 and a second passage 343. The air flowing into the second air space 344 may flow into the first inner air space 345 of the electronic device by passing through the first waterproof member 360. The air flowing into the first inner air space 345 may flow into the second inner air space 347 through the opening 346.

In an example, the housing 310 may form a path through which the air outside the electronic device sequentially passes through a hole (e.g., the hole 321 of FIG. 8), a first passage (e.g., the first passage 342 of FIG. 8), the first air space 341, the second passage 343, the second air space 344, the first waterproof member 360, the first inner air space 345, the opening 346, and the second inner air space 347. However, the disclosure is not limited thereto. For example, at least one of the components of the housing 310 forming the path through which the air passes may be omitted, or at least one component may be additionally included.

Each embodiment herein may be used in combination with any other embodiment(s) described herein.

According to an embodiment, air in the inner air space of the electronic device may move to the outside of the electronic device through a hole (e.g., the hole 321 of FIG. 8). For example, air in the second inner air space 347 of the electronic device may flow into the first air space 345 through the opening 346. Air in the first inner air space 345 may move to the outside of the electronic device by sequentially passing through the first waterproof member 360, the second air space 344, the second passage 343, the first air space 341, a first passage (e.g., the first passage 342 of FIG. 8), and a hole (e.g., the hole 321 of FIG. 8).

In an example, the housing 310 may form a path through which the air in the inner air space of the electronic device sequentially passes through the second inner air space 347, the opening 346, the first inner air space 345, the first waterproof member 360, the second air space 344, the second passage 343, the first air space 341, a first passage (e.g., the first passage 342 of FIG. 8), and a hole (e.g., the hole 321 of FIG. 8). However, the disclosure is not limited thereto. For example, at least one of the components of the housing 310 forming the path through which the air passes may be omitted, or at least one component may be additionally included.

According to an embodiment, the first waterproof member 360 may be disposed between the display panel 320a and the housing 310. For example, the first waterproof member 360 may be disposed between the display panel 320a and the second air space 344. For example, the first waterproof member 360 may cover the second air space 344.

According to an embodiment, the first waterproof member 360 may be attached to the housing 310. For example, the first waterproof member 360 may be attached to the housing 310 by means of an adhesive portion 361. For example, the first waterproof member 360 may be adhered to the housing 310 by means of the adhesive portion 361. The adhesive portion 361 may be disposed between the first waterproof member 360 and the housing 310. In an example, the adhesive portion 361 may be included in the first waterproof member 360.

According to an embodiment, at least part of an air vent passage (e.g., the air vent passage 340 of FIG. 4) may be formed to have an angle of inclination with respect to a direction (e.g., a z-axis direction) from a display (e.g., the window 320 and/or the display panel 320a) toward the rear cover 370. For example, the second passage 343 may be formed to have the angle of inclination with respect to the direction from the display toward the rear cover 370. For example, the second passage 343 may be formed to have an angle of inclination with respect to the first air space 341 and/or the second air space 344. In an embodiment, an angle between the first air space 341 and the second passage 343 may be an acute angle. However, the disclosure is not limited thereto.

According to an embodiment, at least part of the air vent passage is formed to have the angle of inclination, thereby facilitating a process of forming the air vent passage on the housing 310.

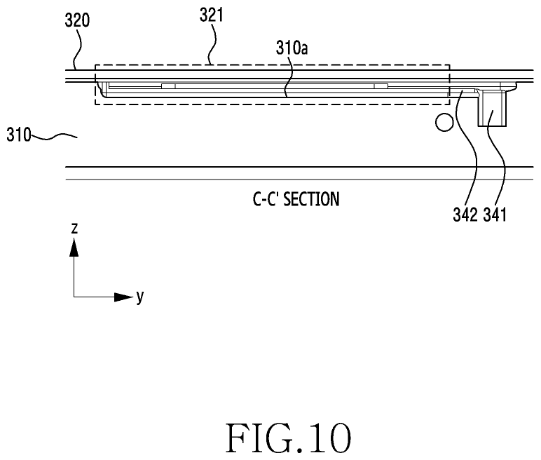

FIG. 10 is a cross-sectional view of the drawing of FIG. 8, taken along the line C-C′ of FIG. 8.

Components of FIG. 10 may be referenced by components of other drawings. The same terms and/or the same reference numerals have been used for the same or substantially the same components as those described above.

Referring to FIG. 10, a housing 310 according to an embodiment may include a recess 310a. The recess 310a may be positioned spaced apart from a display (e.g., a window 320). For example, an air space having a third depth may be formed between the recess 310a and the display (e.g., the window 320).

According to an embodiment, the housing 310 may include a first air space 341 having a first depth in a direction (e.g., a −z direction) from the display (e.g., the window 320) toward the housing 310. In an example, the first depth may be greater than or equal to the third depth. However, the disclosure is not limited thereto.

According to an embodiment, the recess 310a may be positioned at a position corresponding to a hole 321. For example, the recess 310a may be positioned at a position overlapping the hole 321. For example, when looking down the electronic device from above (e.g., when looking down the electronic device in a −z direction), the recess 310a may overlap the hole 321.

According to an embodiment, the recess 310a may be formed at a position corresponding to the hole 321. For example, when looking down the electronic device from above (e.g., when looking down the electronic device in a −z direction), the recess 310a may be formed at a position overlapping the hole 321.

According to an embodiment, the housing 310 may be coupled, directly or indirectly, with a display (e.g., the display panel 320a of FIG. 9) to form an acoustic output path. As an example, an acoustic passage (e.g., the first acoustic passage 332 of FIG. 5A) may include an air space in which the recess 310a and the window 320 are formed spaced apart from each other. Sound (e.g., sound output from an acoustic air space) output from an acoustic component (e.g., the acoustic component 330 of FIG. 4) may be output to the outside of the electronic device through the hole 321 by passing through the acoustic passage.

According to an embodiment, the first air space 341 may be connected, directly or indirectly, to the acoustic passage. For example, the first air space 341 may be connected to the acoustic passage through a first passage 342. The first passage 342 may be positioned between the first air space 341 and the acoustic passage. The first passage 342 may extend from the acoustic passage.

According to an embodiment, the first passage 342 may include an air space formed by coupling the housing 310 and a display. For example, the first passage 342 may include an air space in which the recess 310a and the window 320 are formed spaced apart from each other.

According to an embodiment, air in the inner air space of the electronic device may pass through the first air space 341, the first passage 342, and the hole 321 to move to the outside of the electronic device. The air outside the electronic device may pass through the hole 321, the first passage 342, and the first air space 341 to move to the inside of the electronic device.

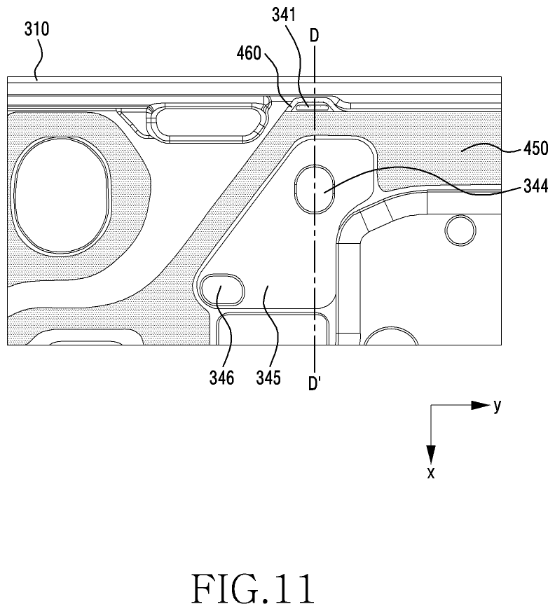

FIG. 11 is a plan view for explaining an electronic device including a second waterproof member according to an embodiment.

Components of FIG. 11 may be referenced by components of other drawings. The same terms and/or the same reference numerals have been used for the same or substantially the same components as those described above.

According to an embodiment, the waterproof member may be disposed on a path for airflow between the outside of the electronic device and an inner air space of the electronic device. For example, the waterproof member may be disposed on an air vent passage (e.g., the air vent passage 340 of FIG. 4). In an example, the waterproof member may include a second waterproof member 460 disposed on a first air space 341.

According to an embodiment, the second waterproof member 460 may be disposed between a first housing 310 and a display (e.g., the window 320 of FIG. 9). For example, the second waterproof member 460 may be disposed between the first air space 341 and the display. For example, the second waterproof member 460 may cover the first air space 341.

According to an embodiment, the second waterproof member 460 may be attached to the housing 310. For example, the second waterproof member 460 may be attached to the housing 310 through an adhesive member 450. For example, the adhesive member 450 may adhere the second waterproof member 460 to the first air space 341.

According to an embodiment, at least part of the adhesive member 450 may be disposed to surround the first air space 341. For example, the adhesive member 450 may be disposed to surround a periphery of an open portion of the first air space 341. For example, the adhesive member 450 may include an opening corresponding to the first air space 341. For example, when the electronic device is viewed (e.g., the display 101 of FIG. 1) in a direction from a display toward the housing 310 (e.g., the first support member 211 of FIG. 3), the opening of the adhesive member 450 may overlap the first air space 341.

According to an embodiment, air in the inner air space of the electronic device may pass through a second inner air space (not shown), an opening 346, a first inner air space 345, a second air space 344, a second passage (not shown), the first air space 341, and the second waterproof member 460. Air outside the electronic device may flow into the inside of the electronic device through a hole (e.g., the hole 321 of FIG. 4), and may flow into the first air space 341 by passing through the second waterproof member 460.

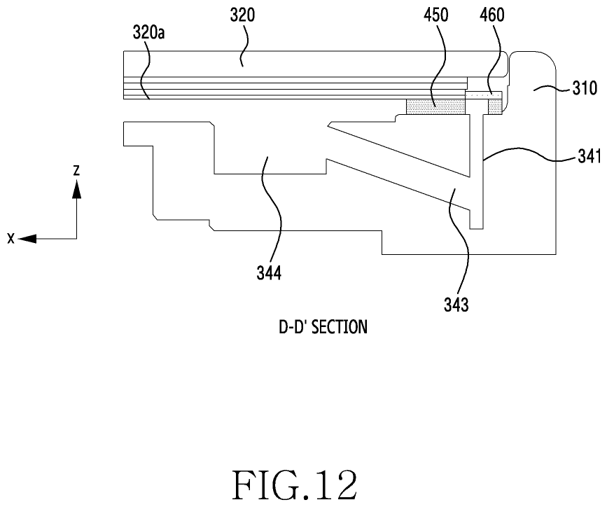

FIG. 12 is a cross-sectional view of the electronic device of FIG. 11, taken along the line D-D′ of FIG. 11.

Components of FIG. 12 may be referenced by components of other drawings. The same terms and/or the same reference numerals have been used for the same or substantially the same components as those described above.

According to an embodiment, a second waterproof member 460 (comprising waterproof and/or water resistant material) may be disposed on, directly or indirectly, an adhesive member 450 comprising adhesive material. For example, the second waterproof member 460 may be disposed between at least the adhesive member 450 and a window. For example, the second waterproof member 460 may cover an opening defined in the adhesive member 450. For example, the second waterproof member 460 may cover a first air space 341 and the opening of the adhesive member 450. For example, the second waterproof member 460 may be disposed between at least a first passage 342 and the first air space 341.

According to an embodiment, the second waterproof member 460 may be fixed to the adhesive member 450. In an example, the second waterproof member 460 and the adhesive member 450 may be formed integrally.

According to an embodiment, air outside the electronic device may flow into the inside of the electronic device through a hole (e.g., the hole 321 of FIG. 4). For example, the air outside of the electronic device may flow into the inside of the electronic device through the hole, and may pass through a first passage (e.g., the first passage 342 of FIG. 6). The air passing through the first passage may pass through the second waterproof member 460. The air passing through the second waterproof member 460 may flow into a second air space 344 for example by sequentially passing through the first air space 341 and a second passage 343. The air flowing into the second air space 344 may flow into the first inner air space (e.g., the first inner air space 345 of FIG. 9) of the electronic device. Although not shown in FIG. 12, the electronic device according to an embodiment may further include a first waterproof member (e.g., the first waterproof member 360 of FIG. 6) which covers the second air space 344. In this case, the air flowing into the second air space 344 may flow into an inner air space of the electronic device (e.g., the first inner air space of the electronic device and the second inner air space of the electronic device) by passing through the first waterproof member.

In an example, a housing 310 may form a path through which the air outside the electronic device sequentially passes through a hole (e.g., the hole 321 of FIG. 4), a first passage (e.g., the first passage 342 of FIG. 6), a second waterproof member 360/460, the first air space 341, the second passage 343, and the second air space 344. However, the disclosure is not limited thereto. For example, at least one of the components of the housing 310 forming the path through which the air passes may be omitted, or at least one component may be additionally included.

According to an embodiment, air in the inner air space of the electronic device may move to the outside of the electronic device through a hole (e.g., the hole 321 of FIG. 4). For example, air in the first inner air space (e.g., the first inner air space 345 of FIG. 9 and/or the second inner air space 347 of FIG. 9) of the electronic device may move to the outside of the electronic device by sequentially passing through the second air space 344, the second passage 343, the first air space 341, the second waterproof member 460, a first passage (e.g., the first passage 342 of FIG. 6), and a hole (e.g., the hole 321 of FIG. 4).

In an example, the housing 310 may form a path through which the air in the inner air space of the electronic device sequentially passes through the second air space 344, the second passage 343, the first air space 341, the second waterproof member 460, the first passage (e.g., the first passage 342 of FIG. 6), and the hole (e.g., the hole 321 of FIG. 4). However, the disclosure is not limited thereto. For example, at least one of the components of the housing 310 forming the path through which the air passes may be omitted, or at least one component may be additionally included.

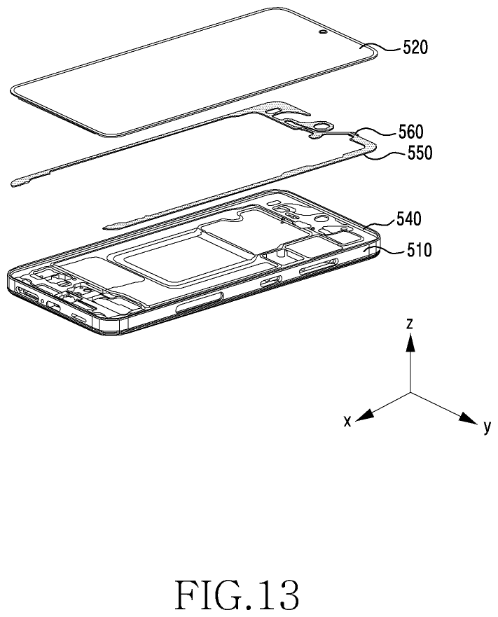

FIG. 13 is an exploded perspective view illustrating a structure of an electronic device including a second waterproof member according to an embodiment.

Components of the electronic device of FIG. 13 may be referenced by components of electronic devices of other drawings. The same terms and/or the same reference numerals have been used for the same or substantially the same components as those described above.

Referring to FIG. 13, the electronic device according to an embodiment may include a window 520, a housing 510 supporting the window 520, an adhesive member 550, and a waterproof member (e.g., a second waterproof member 560). However, the electronic device is not limited to this structure. For example, at least one of the aforementioned components may be omitted in the electronic device, or at least one different component may be additionally included. For example, the electronic device may include a display panel (not shown) disposed below the window 520. In an example, the aforementioned component may be included in at least one different component. For example, the adhesive member 550 and the second waterproof member 560 may be formed integrally.

According to an embodiment, the adhesive member 550 may be disposed between a display (e.g., the window 520) and the housing 510. The adhesive member 550 may be disposed between the display panel and the housing 510. In an example, the adhesive member 550 may be at least partially in contact with the display panel and the housing 510. For example, the adhesive member 550 may adhere the display panel to the housing 510.

According to an embodiment, the adhesive member 550 may include at least one of an adhesive tape, a bond, and silicon. However, the disclosure is not limited thereto. For example, the adhesive member 550 may include the waterproof member 550. For example, the adhesive member 550 may include a waterproof material. Each “waterproof member” and “waterproof material” herein may comprise waterproof and/or water-resistant material.

According to an embodiment, a waterproof member (e.g., the second waterproof member 560) may be disposed between a display (e.g., the window 520) and the housing 510. In an example, the waterproof member may be disposed on a path for airflow between an inner air space of the electronic device and the outside of the electronic device. For example, the waterproof member may be disposed on/at the path to pass the air. For example, the waterproof member may be disposed on/at an air vent passage 540.

According to an embodiment, the waterproof member may include a material which allows gas to pass and blocks or substantially blocks inflow of liquid (e.g., water) and solids. For example, the waterproof member may include a mesh material which may be considered an example waterproof material. However, the waterproof member is not limited to this type.

According to an embodiment, the waterproof member may cover the air vent passage 540. For example, the second waterproof member may be disposed between at least the window 520 and the air vent passage 540.

According to an embodiment, the adhesive member 550 and the waterproof member (e.g., the second waterproof member 560) may separate the inner air space of the electronic device. For example, the adhesive member 550 and the waterproof member may separate the inner air space of the electronic device into a waterproof region and a non-waterproof region. For example, the adhesive member 550 and the waterproof member may separate an air space formed by disposing a display (e.g., a display panel) on the housing 510. For example, the adhesive member 550 and the waterproof member may separate at least an air space formed by coupling the housing 510 and the display panel. For example, the adhesive member 550 and the waterproof member may separate the air space formed by coupling the housing 510 and the display panel into the waterproof region and the non-waterproof region.

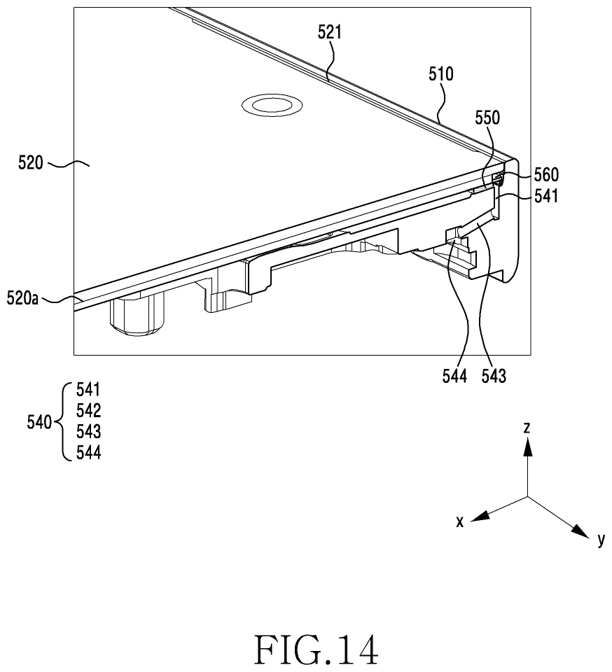

FIG. 14 is a cross-sectional perspective view for explaining a housing including a third passage according to an embodiment.

Components of FIG. 14 may be referenced by components of other drawings. The same terms and/or the same reference numerals have been used for the same or substantially the same components as those described above.

Referring to FIG. 14, the electronic device according to an embodiment may include a first air space 541 formed at a position adjacent to a hole 521. For example, a housing 510 may include and/or help form the first air space 541. For example, an air vent page 540 may include the first air space 541.

According to an embodiment, the first air space 541 may be open in at least a direction (e.g., a +z direction) toward a display (e.g., a window 520). The first air space 541 may be formed to have a first depth in a direction (e.g., a −z direction) toward the housing 510. For example, the first air space 541 may be formed as a recess which is open in a direction toward the window 520.

According to an embodiment, the electronic device may include a first passage (e.g., the first passage 341 of FIG. 6) positioned between at least the hole 521 and the first air space 541. For example, the housing 510 may include a first passage. For example, the air vent passage 540 may include the first passage. The first passage may connect at least the hole 521 and the first air space 541.

According to an embodiment, the electronic device may include a third air space 544 formed to face away from the first air space 541. For example, the housing 510 may include the third air space 544. For example, the air vent passage 540 may include the third air space 544.

According to an embodiment, the third air space 544 may be open in a direction (e.g., the −z direction) opposite a direction in which the first air space 541 is open. For example, the third air space 544 may be formed as a recess which is open in a direction (e.g., the −z direction) from a display (e.g., the window 520 and/or a display panel 520a) toward the housing 510.

According to an embodiment, the electronic device may include a third passage 543 which connects the first air space 541 and the third air space 544. For example, the housing 510 may include the third air space 544. For example, the air vent passage 540 may include the third passage 543.

According to an embodiment, the third passage 543 may be positioned between at least the first air space 541 and the third air space 544. For example, the third passage 543 may be formed between the first air space 541 and the third air space 544. For example, the third passage 543 may be formed between the first air space 541 and the third air space 544 by penetrating the housing 510.

According to an embodiment, a waterproof member may include a second waterproof member 560 disposed between the display and the air vent passage 540. For example, the second waterproof member 560 may be disposed between at least the window 520 and the first air space 541. For example, the second waterproof member 560 may cover the first air space 541.

According to an embodiment, air may flow into the inside of the electronic device through the hole 521. The air flowing thereinto through the hole 521 may flow into the inside of the electronic device by sequentially passing through a first passage (e.g., the first passage 342 of FIG. 6), the second waterproof member 560, the first air space 541, the third passage 543, and the third air space 544.

According to an embodiment, the air inside the electronic device may sequentially pass through the third air space 544, the third passage 543, the first air space 541, the second waterproof member 560, and the first passage, and may move to the outside of the electronic device through the hole 521.

According to an embodiment, liquid may flow into the inside of the electronic device through the hole 521. An adhesive member 550 and the second waterproof member 560 may block or substantially block the liquid from flowing into an inner air space of the electronic device.

According to an embodiment, the first air space 541 may be formed to have a first depth in a direction (e.g., a −z direction) from a display (e.g., the window 520) toward the housing 510 (e.g., the first support member 211 of FIG. 3). The third air space 544 may be formed to have a fourth depth in a direction (e.g., a +z direction) from the housing 510 toward the display.

According to an embodiment, the first depth of the first air space 541 may differ from the fourth depth of the third air space 544. For example, the first depth may be greater than or equal to the fourth depth. However, the disclosure is not limited thereto.

According to an embodiment, the first air space 541 may have a first width in a direction (e.g., an x-axis direction) in which a side of the housing 510 faces. The third air space 544 may have a third width in a direction in which the side of the housing 510 faces. In an example, the third width may be greater than or equal to the first width. However, the disclosure is not limited thereto.

According to an embodiment, at least some of the components of the air vent passage 540 may be omitted in the electronic device, or at least one component may be additionally included. For example, the third air space 544 may be omitted in the electronic device. In an example, the electronic device may further include a second air space (e.g., the second air space 344 of FIG. 7) and a second passage (e.g., the second passage 343 of FIG. 7).

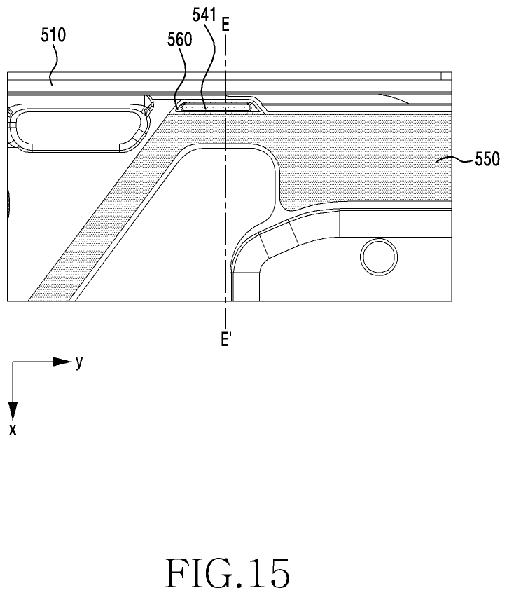

FIG. 15 is a cross-sectional view for explaining a second waterproof member disposed to the electronic device of FIG. 14.

Components of FIG. 15 may be referenced by components of other drawings. The same terms and/or the same reference numerals have been used for the same or substantially the same components as those described above.

According to an embodiment, the waterproof member may be disposed on a path for airflow between the outside of the electronic device and an inner air space of the electronic device. For example, the waterproof member may be disposed on an air vent passage (e.g., the air vent passage 540 of FIG. 14). In an example, the waterproof member may include a second waterproof member 560 disposed on a first air space 541.

According to an embodiment, the second waterproof member 560 may be disposed between at least a housing 510 and a display (e.g., the display 101 of FIG. 1). For example, the second waterproof member 560 may be disposed between the first air space 541 and a window. For example, the second waterproof member 560 may cover the first air space 541.

According to an embodiment, the second waterproof member 560 may be attached to the housing 510. For example, the second waterproof member 560 may be attached (directly or indirectly) to the housing 510 through an adhesive member 550. For example, the adhesive member 550 may adhere the second waterproof member 560 to the first air space 541.

According to an embodiment, at least part of the adhesive member 550 may be disposed to surround the first air space 541. For example, the adhesive member 550 may be disposed to surround a periphery of an open portion of the first air space 541. For example, the adhesive member 550 may include an opening corresponding to the first air space 541. For example, when the electronic device is viewed in a direction from the display (e.g., the display 101 of FIG. 1) toward the housing 510 (e.g., the first support member 211 of FIG. 3), the opening of the adhesive member 550 may overlap the first air space 541.

According to an embodiment, the second waterproof member 560 may be disposed on, directly or indirectly, the adhesive member 550. For example, the second waterproof member 560 may be disposed between at least the adhesive member 560 and the display. For example, the second waterproof member 560 may cover an opening of the adhesive member 550. For example, the second waterproof member 560 may cover the first air space 541 and the opening of the adhesive member 550.

According to an embodiment, the second waterproof member 560 may be fixed to the adhesive member 550. In an example, the second waterproof member 560 and the adhesive member 550 may be formed integrally.

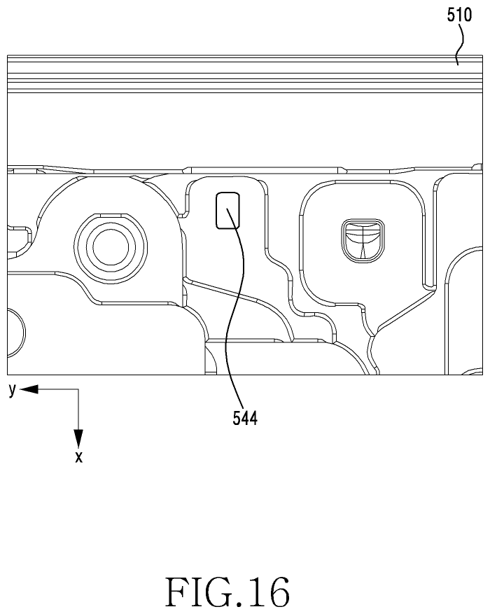

FIG. 16 is a plan view illustrating a rear face of the housing of FIG. 14.

Components of FIG. 16 may be referenced by components of other drawings. The same terms and/or the same reference numerals have been used for the same or substantially the same components as those described above.

According to an embodiment, a housing 510 may include a third air space 544 forming an open hole on a rear face (e.g., a face facing a rear cover) of the housing 510. The third air space 544 may be connected, directly or indirectly, to a third passage (e.g., the third passage 543 of FIG. 14). However, the disclosure is not limited thereto. For example, at least one of the aforementioned component may be omitted in the housing 510, or another component may be additionally included. In an example, the third air space 544 may be omitted in the housing 510. For example, the third passage may form an open hole on the rear face of the housing 510.

Although not shown in FIG. 16, the electronic device may further include a third waterproof member (not shown) disposed to the hole formed on the rear face of the housing 510. The third waterproof member may be disposed between the housing 510 (e.g., the first support member 211 of FIG. 3) and the rear cover (e.g., the rear plate 111 of FIG. 2). For example, the third waterproof member may be disposed between the third air space 544 and the rear cover. For example, the third waterproof member may cover the third air space 544. The third waterproof member may be referenced by the aforementioned waterproof member.

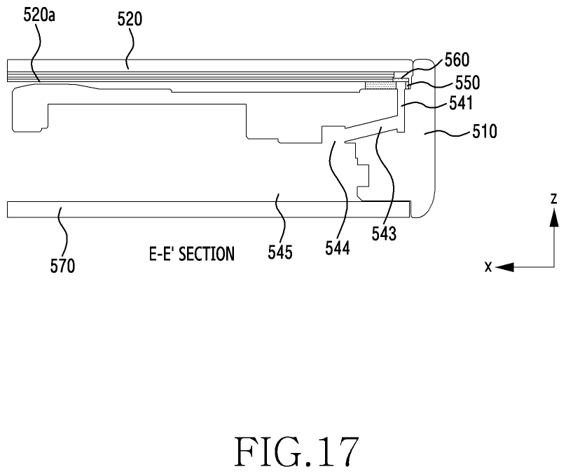

FIG. 17 is a cross-sectional view of the electronic device of FIG. 15, taken along the line E-E′ of FIG. 15.

Components of FIG. 17 may be referenced by components of other drawings. The same terms and/or the same reference numerals have been used for the same or substantially the same components as those described above.

According to an embodiment, the electronic device may include a rear cover 570 (e.g., the rear plate 111 of FIG. 2) disposed on, directly or indirectly, a housing 510 (e.g., the first support member 211 of FIG. 3). The rear cover 570 may be disposed opposite a display (e.g., a window 520 and/or a display panel 520a) with respect to the housing 510. For example, the housing 510 may be disposed between the display (e.g., the display 101 of FIG. 1) and the rear cover 570.

According to an embodiment, an inner air space of the electronic device may include a second inner air space 545 between the housing 510 and the rear cover 570. According to an embodiment, the second inner air space 545 may include an air space formed by the housing 510 and the rear cover 570. For example, the second inner air space 545 may include an air space formed by being surrounded by the housing 510 and the rear cover 570.

According to an embodiment, air outside the electronic device may flow into the inside of the electronic device through a hole (e.g., the hole 521 of FIG. 14). For example, the air outside of the electronic device may flow into the inside of the electronic device through the hole, and may pass through a first passage (e.g., the first passage 342 of FIG. 6). The air passing through the first passage may pass through a second waterproof member 560. The air passing through the second waterproof member 560 may flow into a third air space 544 by sequentially passing through a first air space 541 and a third passage 543. The air flowing into the third air space 544 may flow into the second inner air space 545 of the electronic device. Although not shown in FIG. 17, when the electronic device according to an embodiment includes a third waterproof member which cover the third air space 544, the air flowing into the third air space 544 may flow into the second inner air space 545 of the electronic device by passing through the third waterproof member.

In an example, the housing 510 may form a path through which the air outside the electronic device sequentially passes through a hole (e.g., the hole 521 of FIG. 14), the first passage (e.g., the first passage 342 of FIG. 6), the second waterproof member 560, the first air space 541, the third passage 543, and the third air space 544. However, the disclosure is not limited thereto. For example, at least one of the components of the housing 510 forming the path through which the air passes may be omitted, or at least one component may be additionally included.

According to an embodiment, air in the inner air space of the electronic device may move to the outside of the electronic device through a hole (e.g., the hole 521 of FIG. 14). For example, air in the second inner air space 545 of the electronic device may move to the outside of the electronic device by sequentially passing through the third air space 544, the third passage 543, the first air space 541, the second waterproof member 560, a first passage (e.g., the first passage 342 of FIG. 6), and a hole (e.g., the hole 521 of FIG. 14).

In an example, the housing 510 may form a path through which the air in the second inner air space 545 sequentially passes through the third air space 544, the third passage 543, the first air space 541, the second waterproof member 560, a first passage (e.g., the first passage 342 of FIG. 6), and a hole (e.g., the hole 521 of FIG. 14). However, the disclosure is not limited thereto. For example, at least one of the components of the housing 510 forming the path through which the air passes may be omitted, or at least one component may be additionally included.

According to an embodiment, at least part of an air vent passage (e.g., the air vent passage 540 of FIG. 14) may be formed to have an angle of inclination with respect to a direction (e.g., a z-axis direction) from a display (e.g., the window 520 and/or the display panel 520a) toward the rear cover 570. For example, the third passage 543 may be formed to have an angle of inclination with respect to the direction from the display toward the rear cover 570. For example, the third passage 543 may be formed to have an angle of inclination with respect to the first air space 541 and/or the third air space 544. In an embodiment, an angle between the first air space 541 and the third passage 543 may be an acute angle. However, the disclosure is not limited thereto.

According to an embodiment, at least part of the air vent passage is formed to have the angle of inclination, thereby facilitating a process of forming the air vent passage on the housing 510.

Hereinafter, a case where an electronic device of the disclosure includes a foldable electronic device will be described.

According to an embodiment, a housing (e.g., the housing 310 of FIG. 4) may include a first housing (not shown) and a second housing (not shown). The first housing and the second housing may be rotatably coupled to each other, directly or indirectly. For example, the first housing and the second housing may be coupled to each other in a rotatable manner. For example, the first housing and the second housing may be rotatably coupled to each other via at least one hinge assembly. The first housing may be referenced by the aforementioned housing (e.g., the housing 310 of FIG. 4) of the electronic device.

According to an embodiment, the electronic device may have an unfolded state, a folded state, and/or an intermediate state.

In an embodiment, the unfolded state may include a state where at least part of the housing is unfolded. For example, the unfolded state may include a state where the first housing and the second housing are disposed at an angle of 180 degrees. For example, the unfolded state may include a state where a first side of the first housing is disposed to face the same direction as a first side of the second housing.

In an embodiment, the folded state may include a state where the housing is folded. For example, the folded state may include a state where the first housing and the second housing are disposed to face each other. For example, the folded state may include a state where a first face of the first housing and a first face of the second housing are disposed to face each other. For example, the folded state may include a state where the first face of the first housing and the first face of the second housing are disposed to face away from each other. For example, the folded state may include a state where the first housing and the second housing face each other with a narrow angle (e.g., between 0 and 10 degrees) formed therebetween. However, the disclosure is not limited thereto. For example, the folded state may include a state where a second face opposite the first side of the first housing and a second face opposite the first face of the second housing are disposed to face each other.

In an embodiment, the intermediate state may include a state where the first housing and the second housing are disposed with a certain angle formed therebetween. However, a specific angle formed by the first housing and the second housing when in the unfolded state, the folded state, and the intermediate state is for convenience of explanation, and the disclosure is not limited thereto.

According to an embodiment, a display (e.g., the display 101 of FIG. 1) may include a flexible display disposed across the first housing and the second housing. The flexible display may include a window and/or a display panel. In an example, the window and/or the display panel may include a flexible material. For example, the window may include a flexible window. For example, the display panel may include a flexible display panel. The window may be referenced by a window of the disclosure (e.g., the window 320 of FIG. 7). The display panel may be referenced by a display panel (e.g., the display panel 320a of FIG. 7) of the disclosure.

According to an embodiment, the flexible display may be mounted on, directly or indirectly, a recess formed by the first housing and the second housing. In an embodiment, the flexible display may include a first region and a second region. The first and second regions of the flexible display may be divided about an axis (e.g., a rotation axis) which serves as a reference for folding or unfolding the electronic device. For example, the flexible display may be divided into a folding region having a specific curvature when the electronic device is folded about the axis, the first region adjacent to the first housing with respect to the folding region, and the second region adjacent to the second housing with respect to the folding region. In an example, the first region and the second region may have a shape which is symmetric as a whole about the axis. However, the disclosure is not limited thereto.

According to an embodiment, a configuration of disposing the first and second regions of the flexible display may vary depending on a state of the electronic device. In an example, when the electronic device is in the unfolded state, the first and second regions of the flexible display may form a 180-degree angle with respect to each other. In an example, when the electronic device is in the folded state, the first and second regions of the flexible display may form a narrow angle (e.g., between 0 to 10 degrees) with respect to each other, and may face each other. However, the disclosure is not limited thereto. For example, when the electronic device is in the folded state, the first and second regions of the flexible display may be disposed to form a narrow angle (e.g., between 0 to 10 degrees) with each other and to face away from each other. In an example, when the electronic device is in the intermediate state, the first and second regions of the flexible display may form an angle greater than that in the folded state and smaller than that in the unfolded state. For example, the flexible display may be formed of a curved face having a specific curvature at least in part. In this case, the curvature may be smaller than when the flexible display is in the folded state. However, a specific angle formed by the first region and the second region in the unfolded state, the folded state, and the intermediate state is for convenience of explanation, and the disclosure is not limited thereto.

According to an embodiment, a hole (e.g., the hole 321 of FIG. 4) may be formed between the first housing and the flexible display. For example, the hole may be formed between an edge of the flexible display and a first side of the first housing. For example, the hole may be formed as a gap in which the edge of the flexible display and the first housing are spaced apart from each other by a specific interval. According to an embodiment, the first housing may include the air vent passage (e.g., the air vent passage 340 of FIG. 4).

According to an embodiment, the hole may face the second housing when the electronic device is in the folded state. For example, the hole may face the first face of the second housing. According to an embodiment, the second housing (e.g., the first face of the second housing) may block the air vent passage included in the first housing. For example, the hole may be in contact with the first face of the second housing. For example, the first face of the second housing may cover the hole. Accordingly, air permeability of the electronic device may deteriorate.

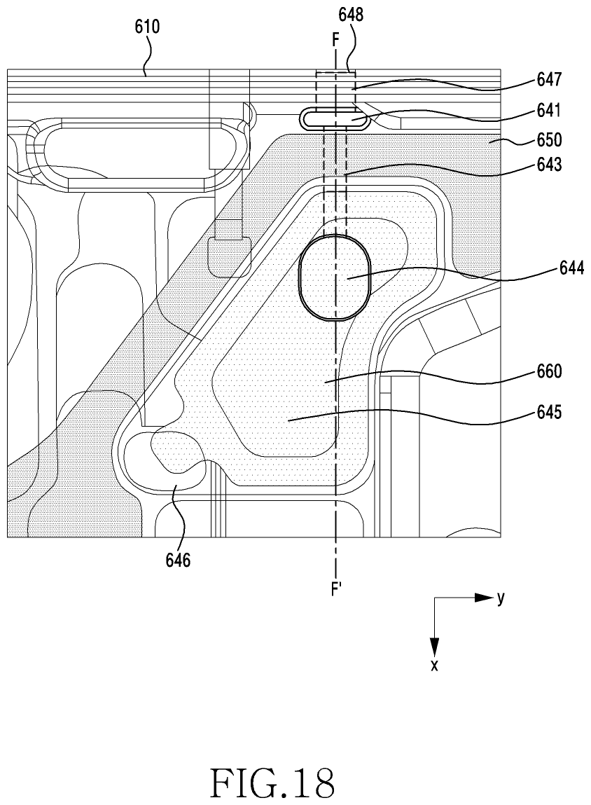

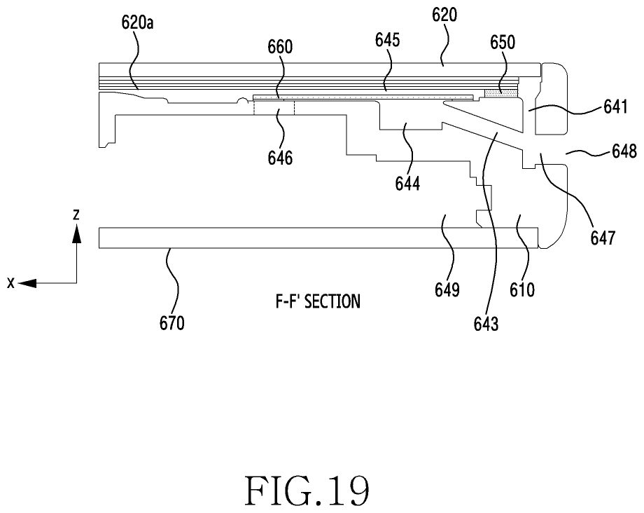

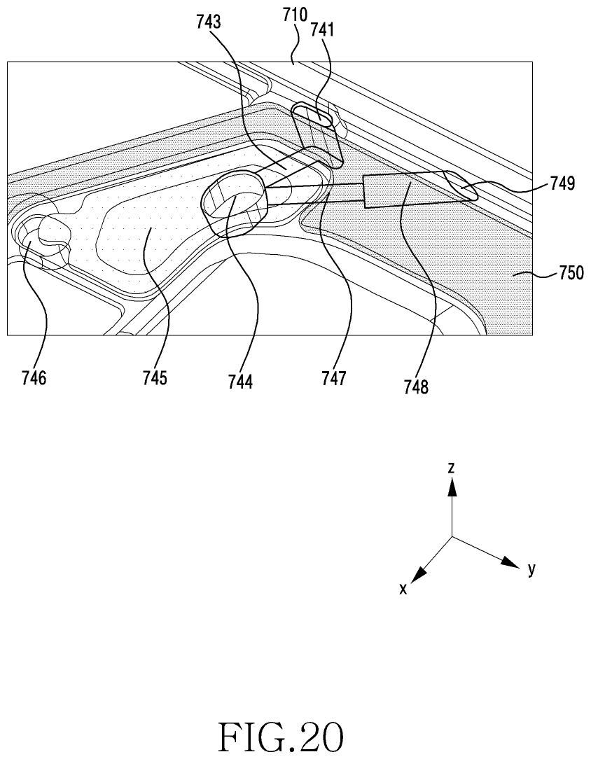

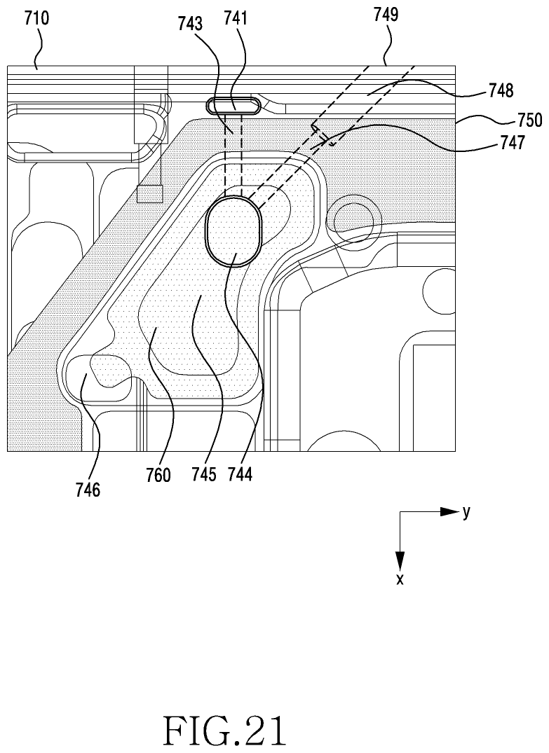

Referring to FIG. 18, FIG. 19, FIG. 20, and FIG. 21, the disclosure may provide an electronic device for improving air permeability of the electronic device when the electronic device is in a folded state.

FIG. 18 is a plan view for explaining a housing including a fourth passage according to an embodiment.

Components of FIG. 18 may be referenced by components of other drawings. The same terms and/or the same reference numerals have been used for the same or substantially the same components as those described above.

Referring to FIG. 18, a housing 610 according to an embodiment may include a fourth passage 647 connected, directly or indirectly, to a first air space 641. For example, an air vent passage (e.g., the air vent passage 340 of FIG. 4) may include the fourth passage 647.

According to an embodiment, the fourth passage 647 may be positioned between the first air space 641 and a side of the first housing 610. For example, the fourth passage 647 may be formed between the first air space 641 and the side of the first housing 610. The fourth passage 647 may be connected, directly or indirectly, to the first air space 641.

According to an embodiment, the fourth passage 647 may be connected to the first air space 641 to connect the outside of the electronic device and an inner air space of the electronic device. For example, the fourth passage 647 may open in a direction (e.g., a −x direction) in which the side of the first housing 610 faces. For example, the fourth passage 647 may form a first hole 648 open in the direction in which the side of the first housing 610 faces. The first hole 648 may be formed on the side of the first housing 610.

According to an embodiment, the fourth passage 647 may be connected to a second air space 644 through the first air space 641. For example, the first air space 641 may be positioned between the fourth passage 647 and the second air space 644. For example, the first air space 641 may be formed between the fourth passage 647 and the second air space 644.

According to an embodiment, the fourth passage 647 may be connected to a second passage 643 through the first air space 641. For example, the first air space 641 may be positioned between the fourth passage 647 and the second passage 643. For example, the first air space 641 may be formed between the fourth passage 647 and the second passage 643. In an example, when looking down the electronic device from above, the fourth passage 647 may be formed to face a direction opposite the second passage 643 with respect to the first air space 641.

According to an embodiment, when the electronic device is in a folded state, air outside the electronic device may flow into the inside of the electronic device through a hole (e.g., the hole 321 of FIG. 4) and/or the first hole 648. For example, the air outside the electronic device may flow into the inside of the electronic device through the first hole 648, and may flow into the inner air space of the electronic device through the fourth passage 647. For example, the air passing through the fourth passage 647 may flow into the second air space 644 by sequentially passing through the first air space 641 and the second passage 643. The air flowing into the second air space 644 may flow into a first inner air space 645 of the electronic device by passing through a first waterproof member 660. The air flowing into the first inner air space 645 may flow into a second inner air space (not shown) of the electronic device through an opening 646.

In an example, the first housing 610 may form a path through which the air outside the electronic device passes through the first waterproof member 660 by sequentially passing through a hole (e.g., the hole 321 of FIG. 4), a first passage (e.g., the first passage 342 of FIG. 6), the first air space 641, the second passage 643, and the second air space 644. In an example, the first housing 610 may form a path through which the air outside the electronic device passes through the first waterproof member 660 by sequentially passing through the first hole 648, the fourth passage 647, the first air space 641, the second passage 643, and the second air space 644. However, the disclosure is not limited thereto. For example, at least one of the components of the first housing 610 forming the path through which the air passes may be omitted, or at least one component may be additionally included. According to an embodiment, the first housing 610 may include the fourth passage 647, so that air permeability of the electronic device may be improved in a folded state of the electronic device.

FIG. 19 is a cross-sectional view of the electronic device of FIG. 18, taken along the line F-F′ of FIG. 18.

Components of FIG. 19 may be referenced by components of other drawings. The same terms and/or the same reference numerals have been used for the same or substantially the same components as those described above. Redundant descriptions will be omitted.

According to an embodiment, the electronic device may include a rear cover 670 disposed on a first housing 610. The rear cover 670 may be disposed opposite a flexible display (e.g., a window 620 and/or a display panel 620a) with respect to the first housing 610. For example, at least part of the first housing 610 may be disposed between the flexible display and the rear cover 670.

According to an embodiment, an inner air space of the electronic device may include a first inner air space 645 between the first housing 610 (e.g., the first support member 211 of FIG. 3) and the display panel 620a, and a second inner air space 649 between the first housing 610 and the rear cover 670. According to an embodiment, the first inner air space 645 may include an air space formed at least partially by the first housing 610, the display panel 620a, an adhesive member 650 comprising adhesive material, and a first waterproof member 660. For example, the first inner air space 645 may include an air space formed by being surrounded by the first housing 610, the display 620a, the adhesive member 650, and the first waterproof member 660.

According to an embodiment, the second inner air space 649 may include an air space formed by at least partially by the first housing 610 and the rear cover 670. For example, the second inner air space 649 may include an air space formed by being surrounded by the first housing 610 and the rear cover 670.

According to an embodiment, when the electronic device is in a folded state, air outside the electronic device may flow into the inside of the electronic device through a hole (e.g., the hole 321 of FIG. 4) and/or a first hole 648. For example, the air flowing into the first inner air space 645 may flow into the second inner air space 649 of the electronic device through an opening 646.

In an example, the first housing 610 may form a path through which the air outside the electronic device passes through the first waterproof member 660 by sequentially passing through a hole (e.g., the hole 321 of FIG. 4), a first passage (e.g., the first passage 342 of FIG. 6), a first air space 641, a second passage 643, a second air space 644, the first inner air space 645, the opening 646, and the second inner air space 649.

In an example, the first housing 610 may form a path through which the air outside the electronic device sequentially passes through the first hole 648, a fourth passage 647, the first air space 641, the second passage 643, the second air space 644, the first waterproof member 660, the first inner air space 645, an opening 636, and the second inner air space 649. However, the disclosure is not limited thereto. For example, at least one of the components of the first housing 610 forming the path through which the air passes may be omitted, or at least one component may be additionally included.

According to an embodiment, when the electronic device is in the folded state, air in the inner air space of the electronic device may move to the outside of the electronic device through a hole (e.g., the hole 321 of FIG. 4) and/or the first hole 648. For example, air in the second inner air space 649 of the electronic device may flow into the first inner air space 645 of the electronic device by passing through the opening 646. The air in the first inner air space 645 of the electronic device may pass through the first waterproof member 660 to move to the outside of the electronic device by sequentially passing through the second air space 644, the second passage 643, the first air space 641, a first passage (e.g., the first passage 342 of FIG. 6), and a hole (e.g., the hole 321 of FIG. 4). The air in the first inner air space 645 of the electronic device may pass through the first waterproof member 660 to move to the outside of the electronic device by sequentially passing through the second air space 644, the second passage 643, the first air space 641, the fourth passage 647, and the first hole 648.

In an example, the first housing 610 may form a path through which air in the first inner air space 645 and/or the second inner air space 649 passes through the first waterproof member 660 to sequentially pass through the second air space 644, the second passage 643, the first air space 641, a first passage (e.g., the first passage 342 of FIG. 6), and a hole (e.g., the hole 321 of FIG. 4). In an example, the first housing 610 may form a path through which the air in the first inner air space 645 and/or the second inner air space 649 passes through the first waterproof member 660 to sequentially pass through the second air space 644, the second passage 643, the first air space 641, the fourth passage 647, and the first hole 648. However, the disclosure is not limited thereto. For example, at least one of the components of the first housing 610 forming the path through which the air passes may be omitted, or at least one component may be additionally included.

FIG. 20 is a perspective view for explaining a housing including a fifth passage and a sixth passage according to an embodiment.

FIG. 21 is a plan view of the electronic device of FIG. 20.

Components of FIG. 20 and FIG. 21 may be referenced by components of other drawings. The same terms and/or the same reference numerals have been used for the same or substantially the same components as those described above.

Referring to FIG. 20 and FIG. 21, a housing 710 according to an embodiment may include a fifth passage 748 connected to a second air space 744 (e.g., the second air space 344 of FIG. 6). For example, an air vent passage (e.g., the air vent passage 340 of FIG. 4) may include the fifth passage 748.

According to an embodiment, the fifth passage 748 may be positioned between the second air space 744 and a side of the first housing 710. For example, the fifth passage 748 may be formed between the second air space 744 and the side of the first housing 710. The fifth passage 748 may be connected to the second air space 744.

According to an embodiment, the fifth passage 748 may be connected to the second air space 744 to connect the outside of the electronic device and an inner air space of the electronic device. For example, the fifth passage 748 may open in a direction (e.g., a −x direction) in which the side of the first housing 710 faces. For example, the fifth passage 748 may form a second hole 749 open in the direction in which the side of the first housing 710 faces. The second hole 749 may be formed on the side of the first housing 710.

According to an embodiment, the housing 710 may include a sixth passage 747. The sixth passage 747 may be positioned between the second air space 744 and the fifth passage 748. For example, the sixth passage 747 may be formed between the second air space 744 and the fifth passage 748. The sixth passage 747 may connect the second air space 744 and the fifth passage 748. In an example, when looking down the electronic device from above, the fifth passage 748 and/or the sixth passage 747 may be positioned to form an angle of inclination with respect to a second passage 743. For example, when looking down the electronic device from above, the fifth passage 748 and/or the sixth passage 747 may be positioned to form an angle of inclination with respect to the second passage 743.

According to an embodiment, a width of the fifth passage 748 may differ from a width of the sixth passage 747. For example, the width of the fifth passage 748 may be greater than the width of the sixth passage 747. However, the disclosure is not limited thereto.

According to an embodiment, when the electronic device is in a folded state, air outside the electronic device may flow into the inside of the electronic device through a hole (e.g., the hole 321 of FIG. 4) and/or the second hole 749. For example, the air outside the electronic device may flow into the inside of the electronic device through the second hole 749, and may flow into the inner air space of the electronic device through the fifth passage 748 and the sixth passage 747. For example, the air passing through the fifth passage 748 and the sixth passage 747 may flow into a first inner air space 745 by sequentially passing through the second air space 744 and a first waterproof member 760. The air flowing into the first inner air space 745 may flow into a second inner air space (not shown) of the electronic device through an opening 746.

In an example, the first housing 710 may form a path through which the air outside the electronic device passes through the first waterproof member 760 by sequentially passing through a hole (e.g., the hole 321 of FIG. 4), a first passage (e.g., the first passage 342 of FIG. 6), a first air space 741, the second passage 743, and the second air space 744.

In an example, the first housing 710 may form a path through which the air outside the electronic device sequentially passes through the second hole 749, the fifth passage 748, the sixth passage 747, the second air space 744, the first waterproof member 760, the first inner air space 745, the opening 746, and the second inner air space. However, the disclosure is not limited thereto. For example, at least one of the components of the first housing 710 forming the path through which the air passes may be omitted, or at least one component may be additionally included.

According to an embodiment, when the electronic device is in the folded state, air in the inner air space of the electronic device may move to the outside of the electronic device through a hole (e.g., the hole 321 of FIG. 4) and/or the second hole 749. For example, air in a second inner air space (not shown) of the electronic device may flow into the first inner air space 745 of the electronic device by passing through the opening 746. The air in the first inner air space 745 of the electronic device may pass through the first waterproof member 760 to move to the outside of the electronic device by sequentially passing through the second air space 744, the second passage 743, the first air space 741, a first passage (e.g., the first passage 342 of FIG. 6), and a hole (e.g., the hole 321 of FIG. 4).

According to an embodiment, the air in the second inner air space (not shown) of the electronic device may pass through the opening 746, the first inner air space 745, and the first waterproof member 760 to move to the outside of the electronic device by sequentially passing through the second air space 744, the sixth passage 747, the fifth passage 743, and the second hole 749.

In an example, the first housing 710 may form a path through which the air in the second inner air space (not shown) passes through the opening 746, the first inner air space 745, and the first waterproof member 760 to sequentially pass through the second air space 744, the second passage 743, the first air space 741, a first passage (e.g., the first passage 342 of FIG. 6), and a hole (e.g., the hole 321 of FIG. 4). In an example, the first housing 710 may form a path through which the air in the second inner air space (not shown) passes through the opening 746, the first inner air space 745, and the first waterproof member 760 to sequentially pass through the second air space 744, the sixth passage 747, the fifth passage 748, and the second hole 749. However, the disclosure is not limited thereto. For example, at least one of the components of the first housing 710 forming the path through which the air passes may be omitted, or at least one component may be additionally included.

According to an embodiment, the first housing 710 may include the fifth passage 748 and/or the sixth passage 747, so that air permeability of the electronic device may be improved in a folded state of the electronic device.

As described above, an electronic device (e.g., the electronic device 100 of FIG. 1) according to an embodiment may include a housing (e.g., the housing 310 of FIG. 4) forming an outer side of the electronic device. The electronic device may include a display panel (e.g., the display panel 320a of FIG. 7) disposed on, directly or indirectly, the housing. The electronic device may include a transparent window (e.g., the transparent window 320 of FIG. 5A) disposed on, directly or indirectly, the display panel. The transparent window may form a front face of the electronic device. The electronic device may include a hole (e.g., the hole 321 of FIG. 4) formed by at least part of the transparent window. The electronic device may include a speaker (e.g., the acoustic component 330 of FIG. 4) which outputs sound to the outside of the electronic device through at least one acoustic passage (e.g., the first acoustic passage 332 or the second acoustic passage 334 of FIG. 5B) formed in the electronic device and through the hole. An acoustic air space in the electronic device may be connected to the outside through the at least one acoustic passage. The electronic device may include an air vent passage (e.g., the air vent passage 340 of FIG. 4) formed at the housing. The air vent passage may be configured to equalize air pressure of an inner air space (e.g., the first inner air space 345 or the second inner air space 347 of FIG. 9) of the electronic device with atmospheric pressure through the hole. The inner air space, independent with the acoustic air space, of the electronic device may be connected to the outside through the air vent passage. The electronic device may include a waterproof member (e.g., the first waterproof member 360 of FIG. 5A and/or the second waterproof member 460 of FIG. 11) disposed on the air vent passage for airflow.

According to an embodiment, the air vent passage may include a first air space (e.g., the first air space 341 of FIG. 6) open in a direction toward the transparent window at a position adjacent to the hole. The air vent passage may be different from the at least one acoustic passage.

According to an embodiment, the air vent passage may include a first passage (e.g., the first passage 342 of FIG. 6) positioned between the hole and the first air space. The first passage may connect the hole and the first air space. The housing may include a recess (e.g., the recess 310a of FIG. 10) spaced apart from the transparent window. The housing may include the recess to form the first passage with the transparent window.

According to an embodiment, the air vent passage may include a second air space (e.g., the second air space 344 of FIG. 6) open in a direction toward the display panel. The air vent passage may include a second passage (e.g., the second passage 343 of FIG. 6) positioned between the first air space and the second air space. The second passage may connect the first air space and the second air space.

According to an embodiment, the electronic device may include an adhesive member (e.g., the adhesive member 450 of FIG. 11) disposed between the display panel and the housing. The electronic device may include a rear cover disposed on the housing. The rear cover may be disposed opposite the display panel. The inner air space of the electronic device may be positioned between the display panel and the second air space. The inner air space of the electronic device may include a first inner air space (e.g., the first inner air space 345 of FIG. 9) formed such that the display panel and the housing are spaced apart from each other by the adhesive member. The inner air space of the electronic device may include a second inner air space (e.g., the second inner air space 347 of FIG. 9) between the housing and the rear cover. The second air space may be connected to the first inner air space. The housing may include an opening penetrating the housing. The opening may connect the first inner air space and the second inner air space.

According to an embodiment, the waterproof member may include a first waterproof member (e.g., the first waterproof member 360 of FIG. 5A) disposed between the display panel and the second air space. The first waterproof member may cover the second air space.

According to an embodiment, the waterproof member may include a second waterproof member (e.g., the second waterproof member 460 of FIG. 11) disposed between the first air space and the transparent window. The second waterproof member may cover the first air space.

According to an embodiment, the air vent passage may include the first air space. The air vent passage may include a third air space (e.g., the third air space 544 of FIG. 14) open in a direction opposite the direction in which the first air space is open. The air vent passage may include a third passage (e.g., the third passage 543 of FIG. 14) positioned between the first air space and the third air space. The third passage may connect the first air space and the third air space.

According to an embodiment, the electronic device may include an adhesive member disposed between the display panel and the housing. The waterproof member may be disposed on the adhesive member.

According to an embodiment, the electronic device may include a rear cover (e.g., the rear cover 370 of FIG. 9) disposed on the housing. The rear cover may be disposed opposite the display panel. At least part of the air vent passage may be formed to have an angle of inclination with respect to a direction from the display panel toward the rear cover.

According to an embodiment, the transparent window may cover the air vent passage such that the air vent passage is not visible from the outside of the electronic device.

According to an embodiment, the housing may include a first housing. The housing may include a second housing rotatably coupled to the first housing about a rotation axis. The hole may be positioned between a side of the first housing and an edge of the transparent window. The hole may be formed such that the first housing and at least part of the edge of the transparent window are spaced apart from each other. The air vent passage may be formed at the housing.

According to an embodiment, the first housing may include a first air space. The housing may include a fourth passage (e.g., the fourth passage 647 of FIG. 19) forming a first hole (e.g., the first hole 648 of FIG. 19) open in a direction in which the side of the first housing faces. The fourth passage may be formed between the first air space and the side of the first housing. The fourth passage may be connected to the first air space.

According to an embodiment, the first housing may include a fifth passage (e.g., the fifth passage 748 of FIG. 20) forming a second hole (e.g., the second hole 749 of FIG. 20) open in a direction in which the side of the first housing faces. The fifth passage may include a second air space. The fifth passage may be formed between the second air space and the side of the first housing. The fifth passage may be connected to the second air space.

According to an embodiment, the first housing may include a sixth passage (e.g., the sixth passage 747 of FIG. 20). The sixth passage may be formed between the second air space and the fifth passage. The sixth passage may connect the second air space and the fifth passage. A width of the fifth passage may be greater than a width of the sixth passage.

According to an embodiment, the electronic device may include an adhesive member (e.g., the adhesive member 350 of FIG. 5B) disposed between the display panel and the housing. The acoustic passage may be formed such that the display panel and the housing are spaced apart from each other by the adhesive member. The acoustic passage may include a first acoustic passage coupling the acoustic air space and the hole and/or a second acoustic passage coupling the acoustic air space and the hole.

As described above, an electronic device (e.g., the electronic device 100 of FIG. 1) according to an embodiment may include a housing (e.g., the side bezel structure 118 of FIG. 1) forming a size of the electronic device. The electronic device may include a display panel (e.g., the display panel 320a of FIG. 7) supported by the housing (e.g., the first support member 211 of FIG. 3). The electronic device may include a front plate (e.g., the window 320 of FIG. 7) supported, directly or indirectly, by the display panel. The front plate may form a front face of the electronic device. The electronic device may include a slit (e.g., the hole 321 of FIG. 4) formed between the side of the electronic device and an edge of the front plate such that the housing and at least part of the edge of the front plate are spaced apart from each other. Sound may be output through the slit. The electronic device may include a speaker (e.g., the acoustic component 330 of FIG. 4) disposed inside the electronic device. The speaker may output sound to the outside of the electronic device through the slit and at least one acoustic passage (e.g., the first acoustic passage 332 and/or the second acoustic passage 334 of FIG. 5B) formed in the electronic device. The housing may include an air vent passage (e.g., the air vent passage 340 of FIG. 4) open in a direction toward the front plate at a position adjacent to the slit, and connects the slit and an inner air space of the electronic device. The housing may include the air vent passage to form a path for airflow between the outside of the electronic device and the inner air space of the electronic device. The electronic device may include a waterproof member (e.g., the first waterproof member 360 of FIG. 5A and/or the second waterproof member 460 of FIG. 11) disposed on the path allowing air to pass therethrough.

According to an embodiment, the air vent passage may include a first air space (e.g., the first air space 341 of FIG. 6) open in a direction toward the front plate at a position adjacent to the second slit. The air vent passage may include a first passage (e.g., the first passage 342 of FIG. 6) positioned between the slit and the first air space. The first passage may connect the slit and the first air space. The housing may include a recess (e.g., the recess 310a of FIG. 10) spaced apart by the front plate. The housing may include the recess to form the first passage with the front plate.

According to an embodiment, the air vent passage may include a second air space (e.g., the second air space 344 of FIG. 6) open in a direction toward the front plate. The air vent passage may include a second passage (e.g., the second passage 343 of FIG. 6) positioned between the first air space and the second air space. The second passage may connect the first air space and the second air space.

According to an embodiment, the electronic device may include a rear plate (e.g., the rear cover 370 of FIG. 9) disposed on the housing. The rear plate may be disposed opposite the front plate. An inner air space of the electronic device may include a first inner air space (e.g., the first inner air space 345 of FIG. 9) between the front plate and the housing. The inner air space of the electronic device may include a second inner air space (e.g., the second inner air space 347 of FIG. 9) between the housing and the rear plate. The second air space may be connected to the first inner air space. The housing may include an opening (e.g., the opening 346 of FIG. 9) penetrating the housing. The opening may connect the first inner air space and the second inner air space.

According to an embodiment, the waterproof member may include a first waterproof member (e.g., the first waterproof member 360 of FIG. 9) disposed between the front plate and the second air space. The first waterproof member may cover the second air space.

According to an embodiment, the waterproof member may include a second waterproof member (e.g., the second waterproof member 460 of FIG. 11) disposed between the first air space and the front plate. The second waterproof member may cover the first air space.

According to an embodiment, the air vent passage may include the first air space. The air vent passage may include a third air space (e.g., the third air space 544 of FIG. 14) open in a direction opposite the direction in which the first air space is open. The air vent passage may include a third passage (e.g., the third passage 543 of FIG. 14) positioned between the first air space and the third air space. The third passage may connect the first air space and the third air space.

According to an embodiment, the electronic device may include an adhesive member (e.g., the adhesive member 350 of FIG. 5A) disposed between the front plate and the housing. The waterproof member may be disposed on the adhesive member.

According to an embodiment, the electronic device may include a rear plate (e.g., the rear cover 370 of FIG. 9) disposed on the housing. The rear plate may be disposed opposite the front plate. At least part of the air vent passage may be formed to have an angle of inclination with respect to a direction from the front plate toward the rear plate.

According to an embodiment, the front plate may cover the air vent passage such that the air vent passage is not visible from the outside of the electronic device.

According to an embodiment, the housing may include the first housing. The housing may include a second housing rotatably coupled to the first housing about a rotation axis. The display panel may include a flexible display panel. The flexible display panel may be disposed on the first housing and the second housing. The slit may be formed between the first housing and the flexible display panel. The first housing may include the air vent passage.

According to an embodiment, the first housing may include the first air space. The housing may include a fourth passage (e.g., the fourth passage 647 of FIG. 19) forming a first hole (e.g., the first hole 648 of FIG. 19) open in a direction in which the side of the first housing faces. The fourth passage may be formed between the first air space and the side of the first housing. The fourth passage may be connected to the first air space.

According to an embodiment, the first housing may include a fifth passage (e.g., the fifth passage 748 of FIG. 20) forming a second hole (e.g., the second hole 749 of FIG. 20) open in a direction in which the side of the first housing faces. The fifth passage may include a second air space. The fifth passage may be formed between the second air space and the side of the first housing. The fifth passage may be connected to the second air space.

According to an embodiment, the first housing may include a sixth passage (e.g., the sixth passage 747 of FIG. 20). The sixth passage may be formed between the second air space and the fifth passage. The sixth passage may connect the second air space and the fifth passage. A width of the fifth passage may be greater than a width of the sixth passage.

In the disclosure, “including at least one of a, b, or c” may mean “including only a”, “including only b”, “including only c”, or “including two or more combinations thereof” (“including a and b”, “including b and c”, “including a and c”, or “including a, b, and c”).

While the disclosure has been shown and described with reference to certain preferred embodiments thereof, it will be understood by those skilled in the art that various changes in form and details may be made therein without departing from the spirit and scope of the disclosure as defined by the appended claims. Therefore, the scope of the disclosure is defined not by the detailed description thereof but by the appended claims, and all differences within equivalents of the scope will be construed as being included in the disclosure While the disclosure has been illustrated and described with reference to various embodiments, it will be understood that the various embodiments are intended to be illustrative, not limiting. It will further be understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

1. An electronic device comprising:
a housing forming at least an outer side of the electronic device;
a display panel disposed on the housing;
a transparent window disposed on the display panel, and forming at least part of a front face of the electronic device;
a hole formed at least by at least portion of the transparent window;
a speaker configured for outputting sound to outside of the electronic device through at least one acoustic passage formed in the electronic device and through the hole, wherein an acoustic air space in the electronic device is connected with outside through at least the at least one acoustic passage;
an air vent passage, formed at and/or proximate the housing and through the hole, configured to equalize air pressure of an inner air space of the electronic device with atmospheric pressure, wherein the inner air space, independent with the acoustic air space, is connected with outside through at least the air vent passage; and
a waterproof member, comprising waterproof and/or water resistant material, disposed on and/or at the air vent passage and configured to allow air to pass through.

2. The electronic device of claim 1, wherein the air vent passage includes a first air space open toward the transparent window at a position adjacent to the hole, and is different from the at least one acoustic passage.

3. The electronic device of claim 2,
wherein the air vent passage includes a first passage positioned between at least the hole and the first air space,
wherein the first passage connects at least the hole and the first air space, and
wherein the housing includes a recess spaced apart from the transparent window to form the first passage with at least the transparent window.

4. The electronic device of claim 2,
wherein the air vent passage includes a second air space open toward the display panel, and a second passage positioned between at least the first air space and the second air space, and
wherein the second passage connects at least the first air space and the second air space.

5. The electronic device of claim 4, further comprising:
an adhesive member, comprising adhesive material, disposed between at least the display panel and the housing; and
a rear cover disposed on the housing and disposed opposite the display panel;
wherein the inner air space of the electronic device includes a first inner air space positioned between at least the display panel and the second air space, and formed by at least the display panel and the housing being spaced apart from each other by at least the adhesive member, and a second inner air space between at least the housing and the rear cover,
wherein the second air space is connected to the first inner air space,
wherein the housing includes an opening penetrating the housing, and
wherein the opening connects at least the first inner air space and the second inner air space.

6. The electronic device of claim 4,
wherein the waterproof member includes a first waterproof member disposed between at least the display panel and the second air space, and
wherein the first waterproof member covers at least the second air space.

7. The electronic device of claim 2,
wherein the waterproof member includes a second waterproof member disposed between at least the first air space and the transparent window, and
wherein the second waterproof member covers at least the first air space.

8. The electronic device of claim 1,
wherein the air vent passage includes a first air space, a third air space open in a direction opposite the direction in which the first air space is open, and a third passage positioned between at least the first air space and the third air space, and
wherein the third passage connects at least the first air space and the third air space.

9. The electronic device of claim 1, further comprising an adhesive member, comprising adhesive material, disposed between at least the display panel and the housing, and
wherein the waterproof member is disposed on the adhesive member.

10. The electronic device of claim 1, further comprising a rear cover disposed on the housing and disposed opposite the display panel, and
wherein at least portion of the air vent passage is formed to comprise an angle of inclination with respect to a direction from the display panel toward the rear cover.

11. The electronic device of claim 1, wherein the transparent window covers the air vent passage such that the air vent passage is not visible from outside of the electronic device.

12. The electronic device of claim 1,
wherein the housing includes a first housing and a second housing rotatably connected to the first housing about a rotation axis,
wherein the hole is positioned between a side of the first housing and an edge of the transparent window, and formed by the first housing and the at least portion of the edge of the transparent window being spaced apart from each other, and
wherein the air vent passage is formed at the housing.

13. The electronic device of claim 12,
wherein the first housing includes a first air space, and a fourth passage forming a first hole open in a direction in which the side of the first housing faces, and
wherein the fourth passage is formed between at least the first air space and the side of the first housing, and is connected to the first air space.

14. The electronic device of claim 12,
wherein the first housing includes a fifth passage forming a second hole open in a direction in which the side of the first housing faces, and
wherein the fifth passage is formed between at least the second air space and the side of the first housing, and is connected to the second air space.

15. The electronic device of claim 14,
wherein the first housing includes a sixth passage,
wherein the sixth passage is formed between at least the second air space and the fifth passage, and connects the second air space and the fifth passage, and
wherein a width of the fifth passage is greater than a width of the sixth passage.

16. The electronic device of claim 1, further comprising
an adhesive member, comprising adhesive material, disposed between at least the display panel and the housing,
wherein the acoustic passage is formed by the display panel and the housing being spaced apart from each other by at least the adhesive member, and
wherein the acoustic passage includes a first acoustic passage connecting the acoustic air space and the hole and/or a second acoustic passage connecting the acoustic air space and the hole.

17. An electronic device comprising:
a housing forming at least part of a side of the electronic device;
a display panel disposed on the housing;
a front plate disposed on the display panel, and forming at least part of a front face of the electronic device;
a slit formed between at least the side of the electronic device and an edge of the front plate such that the housing and at least part of the edge of the front plate are spaced apart from each other, and configured for outputting sound therethrough; and
an acoustic output component, comprising a speaker and/or circuitry, configured for outputting the sound to the outside of the electronic device through at least one acoustic passage formed in the electronic device and through the slit,
wherein the housing includes an air vent passage open toward the front plate and connecting the slit and an inner air space of the electronic device to form a path for airflow between the outside of the electronic device and the inner air space of the electronic device, and
wherein the electronic device further comprises a waterproof member, comprising waterproof and/or water-resistant material, disposed on the path and configured for allowing air to pass therethrough.

18. The electronic device of claim 17, wherein the air vent passage includes a first air space open toward the front plate at a position adjacent to the slit.

19. The electronic device of claim 18,
wherein the air vent passage includes a first passage positioned between at least the slit and the first air space,
wherein the first passage connects at least the slit and the first air space, and
wherein the housing includes a recess spaced apart from the front plate to form the first passage with at least the front plate.

20. The electronic device of claim 18,
wherein the air vent passage includes a second air space open in a direction toward the front plate and a second passage positioned between at least the first air space and the second air space, and
wherein the second passage connects the first air space and the second air space.
